(19) United States
(12) Patent Application Publication
(10) Pub. No.: US 2017/0373468 A1
(43) Pub. Date: Dec. 28, 2017

(54) LIGHT EMITTING DEVICE AND METHOD OF MANUFACTURING THE SAME

(71) Applicant: SONY CORPORATION, TOKYO (JP)

(72) Inventors: SHOICHIRO IZUMI, KANAGAWA (JP); MASARU KURAMOTO, KANAGAWA (JP); NORIYUKI FUTAGAWA, KANAGAWA (JP); TATSUSHI HAMAGUCHI, KANAGAWA (JP)

(21) Appl. No.: 15/544,705

(22) PCT Filed: Oct. 23, 2015
(86) PCT No.: PCT/JP2015/079921

§ 371 Date: Jul. 19, 2017

(30) Foreign Application Priority Data
Feb. 5, 2015 (JP) 2015-021354

(51) Int. Cl. H01S 5/183; H01S 5/026; H01S 5/042; H01S 5/187

(52) U.S. Cl. CPC H01S 5/183; H01S 5/187; H01S 5/026; H01S 5/0425

(57) ABSTRACT

A light emitting device, includes a selective growth mask layer 44; a first light reflection layer 41 thinner than the selective growth mask layer 44; a laminated structure including a first compound semiconductor layer 21, an active layer 23, and a second compound semiconductor layer 22, the first compound semiconductor layer 21 being formed on the first light reflection layer 41; and a second electrode 32 formed on the second compound semiconductor layer 22, and a second light reflection layer 42, in which the second light reflection layer 42 is opposed to the first light reflection layer 41, and the second light reflection layer is not formed on an upper side of the selective growth mask layer 44.

### TECHNICAL FIELD

The present disclosure relates to a light emitting device (specifically, a surface emitting laser device that is also referred to as a vertical cavity laser or VCSEL) and a method of manufacturing the same.

### BACKGROUND ART

A surface emitting laser device normally includes

a first light reflection layer,

a laminated structure including a first compound semiconductor layer formed on the first light reflection layer, an active layer, and a second compound semiconductor layer,

a second electrode and a second light reflection layer formed on the second compound semiconductor layer, and

a first electrode, and

the second light reflection layer is opposed to the first light reflection layer.

In the surface emitting laser device, generally, light is caused to resonate between two light reflection layers (Distributed Bragg Reflector layers, DBR layers), and thus, laser oscillation occurs. Therefore, there is a need to smooth a surface of a semiconductor for forming the DBR layers in sub-nanometer order. When an appropriate smoothness is not obtained, a light reflectance of each DBR layer is reduced, variability of characteristics (oscillation threshold value, etc.) is increased, and then, it is difficult even to obtain laser oscillation.

A method of manufacturing a nitride surface emitting laser by using a selective growth method is known from Japanese Patent Application Laid-open No. 1998-308558. Specifically, the method of manufacturing a nitride semiconductor laser device disclosed in this published unexamined patent application includes the steps of

selectively forming a dielectric multilayer film on a surface of a substrate, the dielectric multilayer film being formed of a dielectric,

causing a lower layer/nitride semiconductor layer to grow on an upper portion of the dielectric multilayer film,

causing an upper layer/nitride semiconductor layer including an active layer to grow on an upper portion of the lower layer/nitride semiconductor layer, and

using the dielectric multilayer film as at least one of reflection mirrors for light emission of the active layer.

Further, in order to cause the lower layer/nitride semiconductor layer to grow on the upper portion of the dielectric multilayer film, a method of forming a seed crystal layer on a surface of a part of the substrate located between the dielectric multilayer film and the dielectric multilayer film and causing the lower layer/nitride semiconductor layer to grow from this seed crystal layer on the basis of lateral direction epitaxial growth is often used.

### CITATION LIST

### Patent Literature

Patent Literature 1: Japanese Patent Application Laid-open No. 1998-308558
Patent Literature 2: Japanese Patent Application Laid-open No. 2000-174328

### Non-Patent Literature

Non-Patent Literature 1: IEEE, Journal of Selected Topics in Quantum Electronics Vol. 15 No. 5 (2011) p. 1390

### DISCLOSURE OF INVENTION

### Technical Problem

Meanwhile, in order to embed the dielectric multilayer film by causing the lower layer/nitride semiconductor layer to grow from the seed crystal layer on the basis of lateral direction epitaxial growth, there is a need to form a thick lower layer/nitride semiconductor layer. However, because the thick lower layer/nitride semiconductor layer absorbs light in itself and diffracts light that propagates through a waveguide, characteristics of a light emitting device are affected. In order to solve such a problem, a method of reducing the thickness of the lower layer/nitride semiconductor layer on the basis of a dry etching method after embedding the dielectric multilayer film by causing the lower layer/nitride semiconductor layer to grow is known. However, in such a method, a new problem that the light emitting device is negatively affected, e.g., it is damaged by etching or the flatness of the surface of the lower layer/nitride semiconductor layer is reduced, may occur. Further, also a method of reducing the thickness of the lower layer/nitride semiconductor layer on the basis of a polishing method is known. However, it is extremely difficult to obtain high controllability of a polishing thickness, i.e., perform control in nanometer order. Furthermore, it is also difficult to polish the lower layer/nitride semiconductor layer to have a uniform thickness in a plane of the substrate for manufacturing the light emitting device. Further, because a projection image of the first electrode and a projection image of the first light reflection layer do not overlap with respect to the laminated structure, diffusion of current that flows from the second electrode to the first electrode in the laminate structure may be insufficient in some cases.

Therefore, a first object of the present disclosure is to provide a light emitting device having a configuration and structure in which the uniformity of a thickness of a compound semiconductor layer can be reliably ensured when a part of the compound semiconductor layer is removed by a polishing method after embedding a light reflection layer by causing the compound semiconductor layer to grow on the basis of lateral direction epitaxial growth, and a method of manufacturing such a light emitting device. Further, a second object of the present disclosure is to provide a light emitting device having a configuration and structure in which diffusion of current that flows in a laminated structure is favorable.

### Solution to Problem

In order to achieve the above-mentioned first object, a light emitting device according to a first aspect of the present disclosure includes:

a selective growth mask layer;

a first light reflection layer thinner than the selective growth mask layer;

a laminated structure including a first compound semiconductor layer, an active layer, and a second compound semiconductor layer, the first compound semiconductor layer being formed on the first light reflection layer; and

a second electrode formed on the second compound semiconductor layer, and a second light reflection layer, in which

the second light reflection layer is opposed to the first light reflection layer.

In order to achieve the above-mentioned first object, a method of manufacturing a light emitting device according to the present disclosure includes:

(A) forming a selective growth mask layer and a first light reflection layer thinner than the selective growth mask layer on a substrate; then,

(B) forming a first compound semiconductor layer on an entire surface, then polishing the first compound semiconductor layer by using the selective growth mask layer as a polishing stopper layer, and thereby removing the first compound semiconductor layer on the selective growth mask layer and leaving the first compound semiconductor layer on the first light reflection layer; after that,

(C) forming an active layer and a second compound semiconductor layer on an entire surface; and then,

(D) forming a second electrode and a second light reflection layer opposed to the first light reflection layer on the second compound semiconductor layer.

In order to achieve the above-mentioned second object, a light emitting device according to a second aspect of the present disclosure includes:

a first light reflection layer;

a laminated structure including a first compound semiconductor layer, an active layer, and a second compound semiconductor layer, the first compound semiconductor layer being formed on the first light reflection layer;

a second electrode formed on the second compound semiconductor layer, and a second light reflection layer; and

a first electrode, in which the second light reflection layer is opposed to the first light reflection layer, and

an impurity-containing compound semiconductor layer is formed in the laminated structure.

### Advantageous Effects of Invention

In the light emitting device according to the first aspect of the present disclosure, the selective growth mask layer and the first light reflection layer thinner than the selective growth mask layer are formed. Therefore, because it only needs to reduce the thickness of the first compound semiconductor layer formed on the first light reflection layer on the basis of a polishing method by using the selective growth mask layer as a polishing stopper layer, it is possible to reduce the thickness of the first compound semiconductor layer with high precision. In the method of manufacturing a light emitting device according to the present disclosure, after forming the selective growth mask layer and the first light reflection layer thinner than the selective growth mask layer, the first compound semiconductor layer is formed, and then, the first compound semiconductor layer is polished using the selective growth mask layer as a polishing stopper layer, thereby removing the first compound semiconductor layer on the selective growth mask layer and leaving the first compound semiconductor layer on the first light reflection layer. Therefore, it is possible to reduce the thickness of the first compound semiconductor layer with high precision. In the light emitting device according to the second aspect of the present disclosure, because the compound semiconductor layer containing an impurity is formed in the laminated structure, it is possible to achieve favorable diffusion of current that flows in the laminated structure. Note that the effects described in the specification are merely examples. The effects of the present invention are not limited thereto. Further, the present invention may provide additional effects other than the above-mentioned effects.

### BRIEF DESCRIPTION OF DRAWINGS

FIG. 1A and FIG. 1B are schematic partial cross-sectional views of a light emitting device in an example 1 and a modified example thereof, respectively.

FIG. 2A is a schematic partial cross-sectional view of another modified example of the light emitting device in the example 1, and FIG. 2B is a schematic partial cross-sectional view of still another modified example of the light emitting device in the example 1 (or, a light emitting device according to a second aspect of the present disclosure).

FIGS. 3A, 3B, 3C, and 3D are each a schematic partial end view of a substrate and the like for describing a method of manufacturing the light emitting device in the example 1.

FIGS. 4A, 4B, and 4C are each a schematic partial end view of the substrate and the like for describing the method of manufacturing the light emitting device in the example 1 following FIG. 3D.

FIGS. 5A and 5B are each a schematic partial end view of a substrate and the like for describing a method of manufacturing a light emitting device in an example 2.

FIGS. 6A and 6B are schematic partial cross-sectional views of light emitting devices in examples 3 and 4, respectively.

FIG. 7 is a schematic partial cross-sectional view of a light emitting device in an example 5.

FIGS. 8A and 8B are schematic partial cross-sectional views of a light emitting device in an example 6 and a modified example thereof, respectively.

FIGS. 9A and 9B are each a schematic partial end view of a laminated structure and the like for describing a method of manufacturing the light emitting device in the example 6.

FIG. 10 is a schematic partial cross-sectional view of a light emitting device in an example 7.

FIGS. 11A and 11B are a schematic partial cross-sectional view of a light emitting device in an example 8 and a schematic partial end view obtained by enlarging a surface region of a substrate, and the like in the light emitting device in the example 8, respectively.

FIGS. 12A, 12B, and 12C are each a schematic partial end view of a laminated structure and the like for describing a method of manufacturing the light emitting device in the example 8.

FIGS. 13A and 13B are each a schematic partial end view of the laminated structure and the like for describing the method of manufacturing the light emitting device in the example 8 following FIG. 12C.

FIGS. 14A and 14B are a schematic partial cross-sectional view of a light emitting device in an example 9 and a schematic partial end view obtained by enlarging a surface region of a substrate, and the like in the light emitting device in the example 2, respectively.

FIGS. 15A and 15B are a schematic partial cross-sectional view of a light emitting device in an example 10 and a schematic partial end view obtained by enlarging a surface region of a substrate, and the like in the light emitting device in the example 3, respectively.

FIGS. 16A and 16B are a schematic partial cross-sectional view of a light emitting device in an example 11 and a schematic partial end view obtained by enlarging a surface region of a substrate, and the like in the light emitting device in the example 4, respectively.

FIGS. 17A and 17B are a schematic partial end view of a light emitting device in an example 12 and a schematic partial cross-sectional view of a light emitting device in an example 13, respectively.

FIG. 18A is a structure schematic view of a multiquantum well structure in an active layer of a light emitting device in an example 14.

FIGS. 19A and 19B are each a schematic partial cross-sectional view of a modified example of the light emitting device in the example 1.

FIGS. 20A and 20B are each a schematic partial cross-sectional view of another modified example of the light emitting device in the example 1.

FIGS. 21A and 21B are each a schematic partial cross-sectional view of still another modified example of the light emitting device in the example 1.

FIG. 22 is a schematic plan view of a first light reflection layer and a selective growth mask layer.

FIG. 23 is a schematic partial cross-sectional view of a light emitting device according to a second aspect of the present disclosure.

FIG. 24 is a schematic partial end view of a light emitting device for describing problems in related art.

FIG. 25 is a graph showing a relationship between light emission recombination time and carrier escape time from a well layer.

### MODE(S) FOR CARRYING OUT THE INVENTION

Hereinafter, the present disclosure will be described on the basis of examples with reference to the drawings. However, the present disclosure is not limited to the examples, and various numerical values and materials in the examples are merely examples. Note that description will be made in the following order.

1. Light emitting device according to First Aspect to Second Aspect of Present Disclosure and Method of Manufacturing the Same, General Description
2. Example 1 (Light Emitting Device according to First Aspect of Present Disclosure and Method of Manufacturing the Same, Light Emitting Device Having First Configuration, Second-Light-Reflection-Layer-Emission-Type Light emitting device, Light Emitting Device according to Second Aspect of Present Disclosure)

### 3. Example 2 (Modification of Method of Manufacturing Light Emitting Device in Example 1)

### 4. Example 3 (Modification of Example 1, Light Emitting Device Having Second Configuration)

### 5. Example 4 (Modification of Example 1, Light Emitting Device Having Third Configuration)

### 6. Example 5 (Modification of Example 1, Light Emitting Device Having Fourth Configuration)

### 7. Example 6 (Modification of Example 1 to Example 5, First-Light-Reflection-Layer Emission-Type Light Emitting Device)

### 8. Example 7 (Modification of Example 1 to Example 6, Light Emitting Device Having Fifth Configuration, Light Emitting Device Having Sixth Configuration)

### 9. Example 8 (Modification of Example 1 to Example 7, Light Emitting Device Having 7-A-th Configuration)

### 10. Example 9 (Modification of Example 8, Light Emitting Device Having 7-Bth Configuration)

### 11. Example 10 (Modification of Example 8, Light Emitting Device Having 7-Cth Configuration)

### 12. Example 11 (Modification of Example 8, Light Emitting Device Having 7-Dth Configuration)

### 13. Example 12 (Modification of Example 6)

### 14. Example 13 (Other Modification of Example 6)

### 15. Example 14 (Modification of Example 1 to Example 13)

### 16. Example 15 (Modification of Example 14)

### 17. Example 16 (Other Modification of Example 14)

### 18. Others

### 1. Light Emitting Device According to First Aspect to Second Aspect of Present Disclosure and Method of Manufacturing the Same, General Description

In a light emitting device according to a first aspect of the present disclosure or a light emitting device in a method of manufacturing a light emitting device according to the present disclosure, one light emitting device may include one first light reflection layer and one selective growth mask layer, one first light reflection layer and a plurality of selective growth mask layers, a plurality of first light reflection layers and one selective growth mask layer, or a plurality of first light reflection layers and a plurality of selective growth mask layers. In the case where one light emitting device includes a plurality of first light reflection layers, i.e., each of the plurality of first light reflection layers constitutes a light emitting device unit and one light emitting device includes a plurality of light emitting device units, each light emitting device unit may be driven on the basis of the same driving condition or a different condition, or a part of the light emitting device units may be driven on the basis of the same driving condition and the remaining part of the light emitting device units may be driven on the basis of a driving condition different therefrom. Further, the selective growth mask layer may be shared between adjacent light emitting devices.

In the light emitting device according to the first aspect of the present disclosure or the light emitting device in the method of manufacturing the light emitting device according to the present disclosure, the same constitution layer (note that the thickness thereof is thinner than that of the selective growth mask layer) as the selective growth mask layer or the first light reflection layer may be formed. The top surface of the selective growth mask layer is located closest to an active layer. In the case where there is a substrate, the thickness of the first light reflection layer is a distance from the interface between the first light reflection layer and the substrate as a reference to the top surface of the first light reflection layer, and the thickness of the selective growth mask layer is a distance from the interface between the first light reflection layer and the substrate as a reference to the top surface of the selective growth mask layer. A second surface of the first compound semiconductor layer to be described later refers to a surface that is in contact with the active layer, a first surface of the first compound semiconductor layer refers to a surface opposed to the second surface, a first surface of the second compound semiconductor layer refers to a surface that is in contact with the active layer, and a second surface of the first compound semiconductor layer refers to a surface opposed to the first surface.

In the method of manufacturing the light emitting device according to the present disclosure,

the step (B) may include forming a lower layer of the first compound semiconductor layer on the entire surface, then polishing the lower layer of the first compound semiconductor layer by using the selective growth mask layer as a polishing stopper layer, and thereby removing the lower layer of the first compound semiconductor layer on the selective growth mask layer and leaving the lower layer of the first compound semiconductor layer on the first light reflection layer, and

the step (C) may include forming an upper layer of the first compound semiconductor layer, the active layer, and the second compound semiconductor layer on the entire surface.

In the method of manufacturing the light emitting device according to the present disclosure including the above-mentioned favorable embodiments,

the selective growth mask layer may be removed between the step (B) and the step (C).

In the light emitting device according to the first aspect of the present disclosure or the light emitting device obtained by the method of manufacturing the light emitting device according to the present disclosure including the various favorable embodiments described above (hereinafter, these light emitting devices are collectively referred to as “the light emitting device according to the first aspect of the present disclosure and the like” in some cases), the difference between the thickness of the selective growth mask layer and the thickness of the first light reflection layer (e.g., distance from the top surface of the selective growth mask layer to the top surface of the first light reflection layer) may be not less than 5×10⁻⁸ m. Examples of the upper limit of the difference of the thickness include, but not limited to, 5×10⁻⁶ m.

In the light emitting device according to the first aspect of the present disclosure including the above-mentioned favorable embodiments and the like,

the first light reflection layer may be formed of a dielectric multilayer film, and

the selective growth mask layer may include, from a side of the active layer, a dielectric multilayer film having the same configuration as that of the dielectric multilayer film constituting the first light reflection layer, and a base layer. Such a configuration is referred to as “the light emitting device having the first configuration” for convenience.

Alternatively, in the light emitting device according to the first aspect of the present disclosure including the above-mentioned favorable embodiments and the like,

the first light reflection layer may be formed of a dielectric multilayer film, and

the selective growth mask layer may include, from a side of the active layer, a polishing stopper layer and a dielectric multilayer film having the same configuration as that of the dielectric multilayer film constituting the first light reflection layer. Such a configuration is referred to as “the light emitting device having the second configuration” for convenience.

Alternatively, in the light emitting device according to the first aspect of the present disclosure including the above-mentioned favorable embodiments and the like,

the selective growth mask layer and the first light reflection layer may be formed on a substrate,

the substrate may have a concave portion and a convex portion,

the selective growth mask layer may be formed in the convex portion of the substrate, and

the first light reflection layer may be formed in the concave portion of the substrate. Such a configuration is referred to as “the light emitting device having the third configuration” for convenience. In the light emitting device having the third configuration, the selective growth mask layer may be formed of a dielectric multilayer film having the same configuration as that of the dielectric multilayer film constituting the first light reflection layer.

Alternatively, in the light emitting device according to the first aspect of the present disclosure including the above-mentioned favorable embodiments and the like, the selective growth mask layer may be formed of a dielectric multilayer film with a thickness different from that of the dielectric multilayer film constituting the first light reflection layer. Such a configuration is referred to as “the light emitting device having the fourth configuration” for convenience. Specifically, for example, it only needs to make the number of layers of the dielectric multilayer film constituting the selective growth mask layer different from the number of layers of the dielectric multilayer film constituting the first light reflection layer.

In the light emitting device according to the first aspect of the present disclosure including the various favorable embodiments and configurations described above and the like, an impurity-containing compound semiconductor layer may be formed in the laminated structure. The impurity-containing compound semiconductor layer is specifically formed in the first compound semiconductor layer constituting the laminated structure (e.g., between a lower layer and an upper layer of the first compound semiconductor layer) or in the second compound semiconductor layer. The same applies to the light emitting device according to the second aspect. Then, in the light emitting device according to the first aspect of the present disclosure and the like or light emitting device according to the second aspect of the present disclosure having such a configuration, an impurity concentration of the impurity-containing compound semiconductor layer may be not less than 10 times an impurity concentration of a compound semiconductor layer adjacent to the impurity-containing compound semiconductor layer, an impurity concentration of the impurity-containing compound semiconductor layer may be not less than 1×10¹⁷/cm³, or an impurity contained in the impurity-containing compound semiconductor layer may include at least one kind of element selected from the group consisting of boron (B), potassium (K), calcium (Ca), sodium (Na), silicon (Si), aluminum (Al), oxygen (O), carbon (C), sulfur (S), halogen (chlorine (Cl) or fluorine (F)), and heavy metal (chromium (Cr), etc.). In the process of forming the laminated structure, the impurity-containing compound semiconductor layer can be formed by performing ion-implantation or impurity diffusion processing, for example. Further, in some cases, the impurity-containing compound semiconductor layer can be formed with an impurity from slurry used when polishing a part of the laminated structure on the basis of a chemical/mechanical polishing method (CMP method). The electrical resistance value of the impurity-containing compound semiconductor layer may be higher or lower than the electrical resistance value of a compound semiconductor layer adjacent to the impurity-containing compound semiconductor layer.

Furthermore, the light emitting device according to the first aspect of the present disclosure including the various favorable embodiments and configurations described above and the like or the light emitting device according to the second aspect of the present disclosure including the various favorable embodiments described above (hereinafter, these light emitting devices are collectively referred to as “the light emitting device according to the present disclosure and the like” in some cases),

the substrate is formed of a GaN substrate,

an off-angle of a plane orientation of a surface of the GaN substrate is not more than 0.4 degrees, favorably, not more than 0.40,

when the area of the GaN substrate is represented by S₀, the total area of the selective growth mask layer and the first light reflection layer is not more than 0.8S₀, and

a thermal expansion relaxation film as the lowermost layer of the first light reflection layer is formed on the GaN substrate (the light emitting device according to the present disclosure and the like having such a configuration is referred to as “the light emitting device having the fifth configuration” for convenience). Further, the linear thermal expansion coefficient CTE of the lowermost layer of the first light reflection layer that is in contact with the GaN substrate satisfies the following relationship,

1×10⁻⁶/K≦CTE≦1×10⁻⁵/K, and favorably,

1×10⁻⁶/K<CTE≦1×10⁻⁵/K

(the light emitting device according to the present disclosure and the like having such a configuration is referred to as “the light emitting device having the sixth configuration” for convenience). Further, in the method of manufacturing the light emitting device according to the present disclosure including the various favorable embodiments and configurations described above and the like,

an off-angle of a plane orientation of a surface of the GaN substrate is not more than 0.4 degrees, favorably, not more than 0.40,

when the area of the GaN substrate is represented by S₀, the total area of the selective growth mask layer and the first light reflection layer is not more than 0.8S₀, and

a thermal expansion relaxation film is formed, as the lowermost layer of the first light reflection layer, on the GaN substrate. Further, the linear thermal expansion coefficient CTE of the lowermost layer of the first light reflection layer that is in contact with the GaN substrate satisfies the following relationship,

1×10⁻⁶/K≦CTE≦1×10⁻⁵/K, and favorably,

1×10⁻⁶/K<CTE≦1×10⁻⁵/K.

As described above, it is possible to reduce the surface roughness of the second compound semiconductor layer by specifying the off-angle of the plane orientation of the crystal surface of the surface of the GaN substrate and the proportion of the total area of the selective growth mask layer and the first light reflection layer. Specifically, it is possible to form the second compound semiconductor layer having excellent surface morphology. As a result, it is possible to obtain the second light reflection layer having excellent smoothness, i.e., a desired light reflectance can be obtained, and the variability of characteristics of the light emitting device is unlikely to occur. Furthermore, by forming a thermal expansion relaxation film or specifying the CTE value, it is possible to prevent such a problem that the first light reflection layer is peeled from the GaN substrate due to the difference between a linear thermal expansion coefficient of the GaN substrate and a linear thermal expansion coefficient of the first light reflection layer from occurring, and provide a light emitting device having high reliability. Furthermore, if the GaN substrate is used, a dislocation is unlikely to occur in the compound semiconductor layer, and it is possible to prevent such a problem that the thermal resistance of light emitting device is increased from occurring. As a result, it is possible to give high reliability to the light emitting device and provide the first electrode (n-side electrode) on the side (back surface side) different from the side of the second electrode (p-side electrode), with the GaN substrate as a reference.

The off-angle of a plane orientation of a surface of the GaN substrate represents an angle formed by a plane orientation of the crystal surface of the surface of the GaN substrate and a normal line of the surface of the GaN substrate in a macroscopic point of view. Further, it is specified that in the light emitting device having the fifth configuration and the light emitting device having the sixth configuration, when the area of the GaN substrate is represented by S₀, the total area of the selective growth mask layer and the first light reflection layer is not more than 0.8S₀. However, “the area S₀ of the GaN substrate” represents the area of the left GaN substrate when the light emitting device is finally obtained. In the light emitting device having the fifth configuration and the light emitting device having the sixth configuration, the lowermost layer of the first light reflection layer does not have a function as a light reflection layer.

In the light emitting device having the fifth configuration, the thermal expansion relaxation film may be formed of at least one kind of material selected from the group consisting of silicon nitride (SiN_{X}), aluminum oxide (AlO_{X}), niobium oxide (NbO_{X}), tantalum oxide (TaO_{X}), titanium oxide (TiO_{X}), magnesium oxide (MgO_{X}), zirconium oxide (ZrO_{X}), and aluminum nitride (AlN_{X}). Note that the value of a suffix “X” or a suffix “Y” and a suffix “Z” to be described later added to the chemical formula of each substance includes not only a value based on the stoichiometry of each substance but also a value deviated from the value based on the stoichiometry. The same applies hereinafter. Then, in the light emitting device having the fifth configuration including such a favorable configuration, when the thickness of the thermal expansion relaxation film is represented by t₁, the light emission wavelength of the light emitting device is represented by λ₀, and the refractive index of the thermal expansion relaxation film is represented by n₁, it is desired to satisfy the following relationship,

t₁=λ₀/(4n₁), and favorably,

t₁=λ₀/(2n₁).

Note that the value of the thickness t₁ of the thermal expansion relaxation film can be essentially an arbitrary value, and may be not more than 1×10⁻⁷ m, for example.

In the light emitting device having the sixth configuration, the lowermost layer of the first light reflection layer may be formed of at least one kind of material selected from the group consisting of silicon nitride (SiN_{X}), aluminum oxide (AlO_{X}), niobium oxide (NbO_{X}), tantalum oxide (TaO_{X}), titanium oxide (TiO_{X}), magnesium oxide (MgO_{X}), zirconium oxide (ZrO_{X}), and aluminum nitride (AlN_{X}). Then, in the light emitting device having the sixth configuration including such a favorable configuration, when the thickness of the lowermost layer of the first light reflection layer is represented by t₁, the light emission wavelength of the lowermost layer of the first light reflection layer is represented by λ₀, and the refractive index of the thermal expansion relaxation film is represented by n₁, it is desired to satisfy the following relationship,

t₁=λ₀/(4n₁), and favorably,

t₁=λ₀/(2n₁).

Note that the value of the thickness t₁ of the lowermost layer of the first light reflection layer can be essentially an arbitrary value, and may be not more than 1×10⁻⁷ m, for example.

A seed crystal layer formed of the same compound semiconductor as the compound semiconductor constituting the first compound semiconductor layer may be formed on the substrate, and the first compound semiconductor layer may be caused to grow from the seed crystal layer. By changing the forming condition of the seed crystal layer and the forming condition of the first compound semiconductor layer, it is possible to form the seed crystal layer and the first compound semiconductor layer formed of the same compound semiconductor material.

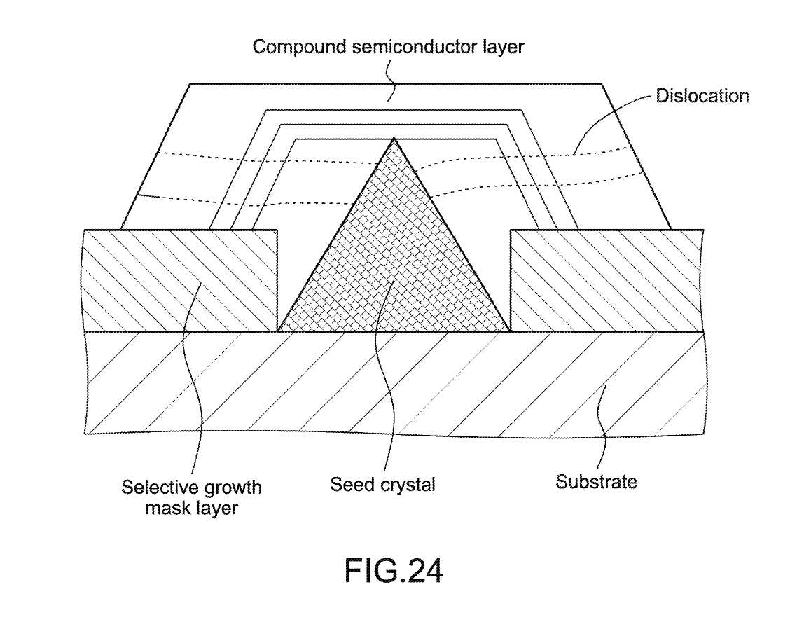

Meanwhile, in the case where the seed crystal layer is thick, when the compound semiconductor layer is caused to grow from this seed crystal layer on the basis of lateral direction epitaxial growth, dislocation from the seed crystal layer extends to a deep part of the first compound semiconductor layer on the first light reflection layer in the horizontal direction (see FIG. 24). As a result, characteristics of the light emitting device may be adversely affected.

Therefore, in the light emitting device according to the present disclosure including the various favorable embodiments and configurations described above and the like,

a seed crystal layer growth region may be provided on a surface of a part of the substrate adjacent to the first light reflection layer,

a seed crystal layer may be formed on the seed crystal layer growth region,

the first compound semiconductor layer may be formed from the seed crystal layer on the basis of lateral direction epitaxial growth, and

the thickness of the seed crystal layer may be smaller than that of the first light reflection layer. The light emitting device having such a configuration according to the present disclosure and the like is referred to as “the light emitting device having the seventh configuration” for convenience. Note that the thickness of the seed crystal layer represents the distance from the interface from the first light reflection layer and the substrate as a reference to the top surface (or vertex) of the seed crystal layer.

Further, in the method of manufacturing the seventh light emitting device, after forming the seed crystal layer growth region on the surface a part of the substrate adjacent to the first light reflection layer, the seed crystal layer thinner than the first light reflection layer is formed on the seed crystal layer growth region, and then, the first compound semiconductor layer is formed from the seed crystal layer on the basis of lateral direction epitaxial growth.

By providing the seed crystal layer growth region, forming the seed crystal layer on the seed crystal layer growth region, and making the thickness of the seed crystal layer smaller than that of the first light reflection layer as described above, it is possible to reliably prevent dislocation from the seed crystal layer from extending to a deep part of the first compound semiconductor layer on the first light reflection layer in the horizontal direction.

In the light emitting device having the seventh configuration, when the thickness of the seed crystal layer is represented by T_{seed} and the thickness of the first light reflection layer is represented by T₁, it is desirable to satisfy the following relationship,

0.1≦T_{seed}/T1<1.

In the light emitting device having the seventh configuration including the above-mentioned favorable configuration,

a concavo-convex portion may be formed on a surface of a part of the substrate adjacent to the first light reflection layer, and

a convex portion may constitute the seed crystal layer growth region. Such a configuration is referred to as “the light emitting device having the 7-A-th configuration” for convenience. In the light emitting device having the 7-A-th configuration,

the cross-sectional shape obtained by cutting a part of the substrate adjacent to the first light reflection layer on the virtual vertical surface including a normal line that passes through the central point of the first light reflection layer may be a shape in which a concave portion, the convex portion, and the concave portion are arranged in the stated order, and

the top surface of the convex portion may constitute the seed crystal layer growth region. Further, in this case, when the length of the convex portion and the total length of the concave portion in the virtual vertical surface are respectively represented by L_{cv} and L_{cc} the following relationship,

0.2≦L_{cv}/(L_{cv}+L_{cc})≦0.9

may be satisfied. The number of convex portions may be two or more. Examples of the cross-sectional shape of the concave portion when the concave portion is cut on the virtual vertical surface include a rectangular shape, a triangular shape, a trapezoidal shape (the upper base is the bottom surface of the concave portion), a shape obtained by making corner portions of these shapes round, and a fine concavo-convex shape. Examples the depth of the concave portion include not less than 0.1 μm, and favorably, not less than 0.5 μm.

Alternatively, in the light emitting device having the seventh configuration including the above-mentioned favorable configuration,

a concavo-convex portion may be formed on a surface of a part of the substrate adjacent to the first light reflection layer, and

a concave portion may constitute the seed crystal layer growth region. Such a light emitting device having the seventh configuration of this configuration is referred to as “the light emitting device having the 7-B-th configuration” for convenience. In the light emitting device having the 7-B-th configuration,

the cross-sectional shape obtained by cutting a part of the substrate adjacent to the first light reflection layer on the virtual vertical surface including a normal line that passes the central point of the first light reflection layer may be a shape in which the convex portion, the concave portion, and the convex portion are arranged in the stated order, and

the bottom surface of the concave portion may constitute the seed crystal layer growth region. Further, in this case, when the length of the concave portion and the total length of the convex portion in the virtual vertical surface are respectively represented by L_{cc} and L_{cv}, the following relationship,

0.2≦L_{cc}/(L_{cv}+L_{cc})≦0.9,

may be satisfied. The number of concave portions may be two or more. Examples of the shape of the top surface of the convex portion when the convex portion is cut on the virtual vertical surface include a flat shape, an upward curved shape, a downward curved shape, and a fine concavo-convex shape. Examples the depth of the concave portion include not less than 0.1 μm, and favorably, not less than 0.5 μm.

Alternatively, in the light emitting device having the seventh configuration including the described above favorable configuration,

a part of a substrate adjacent to the first light reflection layer may have a structure in which a non-crystal growth portion, a flat portion, and a non-crystal growth portion are arranged in the stated order, and

the flat portion may constitute the seed crystal layer growth region. Such a light emitting device having the seventh configuration of this configuration is referred to as “the light emitting device having the 7-C-th configuration” for convenience. In the light emitting device having the 7-C-th configuration, when the length of the flat portion and the total length of the non-crystal growth portion in the virtual vertical surface including a normal line that passes through the central point of the first light reflection layer are respectively represented by L_{flat} and Lₙₒᵥ, the following relationship,

0.2≦L_{flat}/(L_{flat}+Lₙₒ)≦0.9,

may be satisfied. The number of flat portions may be two or more.

Alternatively, in the light emitting device having the seventh configuration including the above-mentioned favorable configuration,

a part of the substrate adjacent to the first light reflection layer may have a structure in which the concavo-convex portion, the flat portion, and a concavo-convex portion are arranged in the stated order, and

the flat portion may constitute the seed crystal layer growth region. Such a light emitting device having the seventh configuration of this configuration is referred to as “the light emitting device having the 7-D-th configuration” for convenience. In the light emitting device having the 7-D-th configuration, when the length of the flat portion and the total length of the concavo-convex portion in the virtual vertical surface including a normal line that passes the central point of the first light reflection layer are respectively referred to as L_{flat} and L_{cc-cv}, the following relationship,

0.2≦L_{flat}/(L_{flat}+L_{cc-cv})≦0.9,

may be satisfied. The number of flat portions may be two or more.

Furthermore, in the light emitting device having the seventh configuration including the above-mentioned various favorable configurations, the light emitting device having the 7-A-th configuration to the light emitting device having the 7-D-th configuration, the cross-sectional shape of the seed crystal layer (specifically, the cross-sectional shape of the seed crystal layer in the above-mentioned virtual vertical surface) may be an isosceles triangle, an isosceles trapezoid, or a rectangular shape.

Furthermore, in the light emitting device having the seventh configuration including the above-mentioned various favorable configurations, the light emitting device having the 7-A-th configuration to the light emitting device having the 7-D-th configuration,

when the length of a region of the substrate located between the first light reflection layer and the selective growth mask layer adjacent thereto when the light emitting device is cut on the virtual vertical surface including a normal line that passes through the central points of the first light reflection layer and the selective growth mask layer adjacent thereto is represented by L₀,

a dislocation density of a region of the first compound semiconductor layer located on the upper side of the region of the substrate in the virtual vertical surface is represented by D₀, and

a dislocation density of a region of the first compound semiconductor layer located on the region of the first light reflection layer from the edge of the first light reflection layer to the distance L₀ in the virtual vertical surface is represented by D₁, the following relationship,

D₁/D₀≦0.2

may be satisfied. Note that that following relationships,

L₀=L_{cv}+L_{cc} and

L₀=L_{flat}+L_{cc-cv}, are satisfied.

In the light emitting device according to the present disclosure including the various favorable embodiments and configurations described above and the like, the plane shape of the selective growth mask layer or the first light reflection layer may be various polygons including a regular hexagon, a circular shape, an elliptical shape, a lattice shape (rectangular), an island shape, or a stripe shape. The cross-sectional shape of the selective growth mask layer or the first light reflection layer may be a rectangular shape, but is favorably a trapezoidal shape. That is, the side surface of the selective growth mask layer or the first light reflection layer is favorably a normal tapered shape. Examples of the method of forming the selective growth mask layer or the first light reflection layer include a physical vapor deposition method (PVD method) such as a sputtering method, a chemical vapor deposition method (CVD method), and a combination of a coating method and a lithography technology or an etching technology.

Examples of the substrate specifically include a GaN substrate, a sapphire substrate, a GaAs substrate, and a silicon semiconductor substrate. Examples of the material forming the first compound semiconductor layer, the active layer, and the second compound semiconductor layer specifically include a GaN-based compound semiconductor, and more specifically, a AlInGaN-based compound semiconductor.

Meanwhile, in the method of manufacturing a nitride semiconductor laser device disclosed in the above-mentioned published unexamined patent application (Japanese Patent Application Laid-open No. 1998-308558), a substrate different from a nitride semiconductor is used. However, when such a substrate is used, specifically, when a sapphire substrate is used, for example, many dislocations occur due to lattice inconsistency between the GaN-based compound semiconductor layer and the sapphire substrate, which significantly and adversely affects the reliability of the light emitting device. Further, the thermal conductivity of the sapphire substrate is lower than that of a normal semiconductor substrate, and thus, the thermal resistance of the light emitting device is very large. This is a factor of an increase in oscillation threshold value current, reduction in optical output, reduction in device lifetime, and the like. In addition, because the sapphire substrate does not have electrical conductivity, the first electrode (n-side electrode) cannot be provided to the back surface of the substrate, and there is a need to provide the first electrode on the same side as the side on which the second electrode (p-side electrode) is provided. Therefore, such a problem that the device area is increased and the productivity is poor occurs. Furthermore, problems such as peeling of the first light reflection layer from the substrate due to the difference between the linear thermal expansion coefficient of the substrate and the linear thermal expansion coefficient of the first light reflection layer and variability of characteristics (e.g., variability of a light reflectance) due to the roughness of the surface of the nitride semiconductor layer when the nitride semiconductor layer including the active layer is caused to grow are not referred to at all in the above-mentioned published unexamined patent application. It is possible to reliably avoid such a problem by using a GaN substrate as the substrate, and a GaN-based compound semiconductor as the material forming the first compound semiconductor layer, the active layer, and the second compound semiconductor layer.

In the light emitting device according to the present disclosure including the various favorable embodiments and configurations described above and the like or the method of manufacturing the light emitting device according to the present disclosure including the various favorable embodiments and configurations described above, the substrate may remain to be left, or the active layer, the second compound semiconductor layer, the second electrode, and the second light reflection layer may be successively formed on the first compound semiconductor layer, and then, after fixing the second light reflection layer on the supporting substrate, the substrate may be removed by using the selective growth mask layer or the first light reflection layer as a polishing stopper layer, thereby exposing the first compound semiconductor layer (first surface of the first compound semiconductor layer), the selective growth mask layer, and the first light reflection layer. Then, it only needs to form the first electrode on the first compound semiconductor layer (first surface of the first compound semiconductor layer).

In the case where the substrate is formed of a GaN substrate, removal of the GaN substrate may be performed on the basis of a chemical/mechanical polishing method (CMP method). Note that it only needs to perform removal of a part of the GaN substrate or reduce the thickness of the GaN substrate first with a wet etching method using an alkali solution such as a sodium hydroxide solution and a potassium hydroxide solution, an ammonia solution+hydrogen peroxide water, a sulfuric acid solution+hydrogen peroxide water, a hydrochloric acid solution+hydrogen peroxide water, a phosphate solution+hydrogen peroxide water, and the like, a dry etching method, a lift-off method using laser, a mechanical polishing method, and the like, or a combination thereof, and then, a chemical/mechanical polishing method needs to be performed, thereby exposing the first compound semiconductor layer (first surface of the first compound semiconductor layer), the selective growth mask layer, and the first light reflection layer.

Furthermore, in the light emitting device according to the present disclosure including the various favorable embodiments and configurations described above and the like, the surface roughness Ra of the second compound semiconductor layer (second surface of the second compound semiconductor layer) is favorably not more than 1.0 nm. The surface roughness Ra is defined in JIS B-610:2001, and specifically, it is possible to measure the surface roughness Ra on the basis of observation based on AFM or cross-sectional TEM.

In the light emitting device according to the present disclosure including the various favorable embodiments and configurations described above and the like, the distance from the first light reflection layer to the second light reflection layer is favorably not less than 0.15 μm and not more than 50 μm.

Furthermore, in the light emitting device according to the present disclosure including the various favorable embodiments and configurations described above and the like, it is favorable that the area centroid of the second light reflection layer is not on the normal line of the first light reflection layer that passes through the area centroid of the first light reflection layer.

Furthermore, in the light emitting device according to the present disclosure including the various favorable embodiments and configurations described above and the like, it is favorable that the area centroid of the active layer (specifically, the area centroid of the active layer constituting the device region, the same applies hereinafter) is not on the normal line of the first light reflection layer that passes through the area centroid of the first light reflection layer.

When the first compound semiconductor layer is formed is formed on the basis of lateral direction growth by using a method of lateral direction epitaxial growth method such as an ELO (Epitaxial Lateral Overgrowth) method on the substrate on which the first light reflection layer and the first compound semiconductor layer that epitaxially grows from the edge portion of the first light reflection layer to the center portion of the first light reflection layer is associated, many crystal defects are caused in the associated portion in some cases. When the associated portion where there are many crystal defects is located on the center portion of the device region (to be described later), characteristics of the light emitting device may be adversely affected. By employing the embodiment in which the area centroid of the second light reflection layer is not on the normal line of the first light reflection layer that passes through the area centroid of the first light reflection layer or the embodiment in which the area centroid of the active layer is not on the normal line of the first light reflection layer that passes through the area centroid of the first light reflection layer, as described above, it is possible to reliably prevent the characteristics of the light emitting device from being adversely affected.

In the light emitting device according to the present disclosure including the various favorable embodiments and configurations described above and the like, light generated in the active layer may be emitted to the outside via the second light reflection layer (hereinafter, referred to as the second-light-reflection-layer-emission-type light emitting device for convenience), or emitted to the outside via the first light reflection layer (hereinafter, referred to as the first-light-reflection-layer-emission-type light emitting device for convenience). Note that in the first-light-reflection-layer-emission-type light emitting device, the substrate may be removed as described above in some cases.

Then, when the area of a part of the first light reflection layer that is in contact with the first surface of the first compound semiconductor layer (a part of the first light reflection layer opposed to the second light reflection layer) is represented by S₁ and the area of a part of the second light reflection layer opposed to the second surface of the second compound semiconductor layer (a part of the second light reflection layer opposed to the first light reflection layer) is represented by S2, it is favorable that the first-light-reflection-layer-emission-type light emitting device satisfies the following relationship,

S₁>S₂, and

the second-light-reflection-layer-emission-type light emitting device satisfies the following relationship,

S₁<S₂.

However, it is not limited thereto.

Further, in the embodiment in which the area centroid of the second light reflection layer is not on the normal line of the first light reflection layer that passes through the area centroid of the first light reflection layer and the embodiment in which the area centroid of the active layer is not on the normal line of the first light reflection layer that passes through the area centroid of the first light reflection layer, when the area of a part of the first light reflection layer that is in contact with the first surface of the first compound semiconductor layer (a part of the first light reflection layer opposed to the second light reflection layer), which constitutes the device region (to be described later), is represented by S₃, and the area of a part of the second light reflection layer opposed to the second surface of the second compound semiconductor layer (a part of the second light reflection layer opposed to the first light reflection layer), which constitutes the device region, is represented by S₄, it is favorable that the first-light-reflection-layer-emission-type light emitting device satisfies the following relationship,

S₃>S₄, and

the second-light-reflection-layer-emission-type light emitting device satisfies the following relationship,

S₃<S₄.

However, it is not limited thereto.

In the first-light-reflection-layer-emission-type light emitting device, in the case where the substrate is removed, the second light reflection layer may be fixed to the supporting substrate, as described above. In the first-light-reflection-layer-emission-type light emitting device, in the case where the substrate is not removed, it only needs to form the first electrode on the exposed surface of the substrate. Further, in the case where the substrate is removed, examples of arrangement states of the first light reflection layer and the first electrode in the first surface of the first compound semiconductor layer include the state where the first light reflection layer and the first electrode are in contact with each other, the state where the first light reflection layer and the first electrode are separated from each other, and the state where the first electrode is formed over the edge of the first light reflection layer in some cases. Alternatively, the first light reflection layer and the first electrode may be separated from each other, i.e., they may have an offset, and the separation distance may be not more than 1 mm.

Furthermore, in the light emitting device according to the present disclosure including the various favorable embodiments and configurations described above and the like, the first electrode may be formed of a metal, an alloy, or a transparent conductive material, and the second electrode may be formed of a transparent conductive material. By forming the second electrode from a transparent conductive material, it is possible to extend current in a lateral direction (in-plane direction of the second compound semiconductor layer) and efficiently supply current to the device region (to be described next).

The “device region” indicates a region into which constricted current is injected (current constriction region), a region in which light is confined by the difference of a refractive index and the like, a region in which laser oscillation occurs of the region sandwiched by the first light reflection layer and the second light reflection layer, or a region that actually contributes laser oscillation of the region sandwiched by the first light reflection layer and the second light reflection layer.

The light emitting device may be formed of a surface emitting laser device that emits light from the top surface of the first compound semiconductor layer via the first light reflection layer as described above, or a surface emitting laser device that emits light from the top surface of the second compound semiconductor layer via the second light reflection layer.

In the light emitting device according to the present disclosure including the various favorable embodiments and configurations described above and the like, the laminated structure including the first compound semiconductor layer, the active layer, and the second compound semiconductor layer may be specifically formed of a GaN-based compound semiconductor, as described above. Note that examples of the GaN-based compound semiconductor include, more specifically, GaN, AlGaN, InGaN, and AlInGaN. Furthermore, the compound semiconductor may contain a boron (B) atom, a thallium (Tl) atom, an arsenic (As) atom, a phosphorous (P) atom, an antimony (Sb) atom as desired. It is desirable that the active layer has a quantum well structure. Specifically, the active layer may have a single quantum well structure (SQW structure), or a multiquantum well structure (MQW structure). The active layer having a quantum well structure has a structure in which at least one layer of a well layer and a barrier layer is laminated. Examples of the combination of (a compound semiconductor forming the well layer and a compound semiconductor forming the barrier layer) include (In_{Y}Ga_{(1-y)}N, GaN), (In_{Y}Ga_{(1-y)}N, In_{Z}Ga_{(1-z)}N) [where y>z], and (In_{Y}Ga_{(1-y)}N, AlGaN). The first compound semiconductor layer may be formed of a first conductive type (e.g., n-type) compound semiconductor, and the second compound semiconductor layer may be formed of a second conductive type (e.g., p-type) compound semiconductor that is different from the first conductive type compound semiconductor. The first compound semiconductor layer and the second compound semiconductor layer are respectively referred to also as a first cladding layer and a second cladding layer. It is favorable that a current constriction structure is formed between the second electrode and the second compound semiconductor layer. The first compound semiconductor layer and the second compound semiconductor layer may each be a layer having a single structure, a layer having a multiple layer structure, or a layer having a superlattice structure. Furthermore, they may each be a layer including a composition gradient layer or a concentration gradient layer.

In order to achieve the current constriction structure, a current constriction layer formed of an insulating material (e.g., SiO_{X}, SiN_{X}, and AlO_{X}) may be formed between the second electrode and the second compound semiconductor layer, a mesa-structure may be formed by etching the second compound semiconductor layer with an RIE method or the like, a current constriction region may be formed by partially oxidizing a partial layer of the laminated second compound semiconductor layer from a lateral direction, a region in which the conductivity is reduced may be formed by performing ion-implantation of an impurity on the second compound semiconductor layer, or these may be appropriately combined together. Note that the second electrode needs to be electrically connected to a part of the second compound semiconductor layer through which current flows by current constriction.

It has been known that the characteristics of the GaN substrate are changed to polarity/non-polarity/semi-polarity depending on the growth surface. Any of the main surfaces of the GaN substrate can be used for forming a compound semiconductor layer. Further, regarding the main surface of the GaN substrate, a surface obtained by displacing, in a particular direction, the surface orientation of the crystal surface called by names such as so-called A surface, B surface, C surface, R surface, M surface, N surface, S surface, and the like (including a surface in which the off-angle is 0 degrees) is used depending on the crystalline structure (e.g., cubic crystal and hexagonal crystal). Examples of the method of forming the various compound semiconductor layers constituting the light emitting device include a metal organic chemical vapor deposition/metal organic vapor phase epitaxy method (MOCVD method, MOVPE method), a molecular beam epitaxy method (MBE method), and a hydride vapor phase epitaxy method in which a halogen contributes to transportation or reaction.

Note that examples of the organic gallium source in the MOCVD method include trimethylgallium (TMG) and triethylgallium (TEG), and examples of the nitrogen source gas include an ammonia gas and hydrazine. In forming an n-type conductive type GaN-based compound semiconductor layer, for example, it only needs to add silicon (Si) as an n-type impurity (n-type dopant). In forming a p-type conductive type GaN-based compound semiconductor layer, for example, it only needs to add magnesium (Mg) as a p-type impurity (p-type dopant). In the case where atoms constituting the GaN-based compound semiconductor layer include aluminum (Al) or indium (In), it only needs to use trimethylaluminium (TMA) as an Al source, and trimethylindium (TMI) as an In source. Furthermore, it only needs to use a monosilane gas (SiH₄ gas) as a Si source, and biscyclopentadienyl magnesium, methylcyclopentadienyl magnesium, or biscyclopentadienyl magnesium (Cp₂Mg) as an Mg source. Note that examples of the n-type impurity (n-type dopant) other than Si include Ge, Se, Sn, C, Te, S, O, Pd, and Po, and examples of the p-type impurity (p-type dopant) other than Mg include Zn, Cd, Be, Ca, Ba, C, Hg, and Sr.

The supporting substrate may be formed of, for example, various substrates such as a GaN substrate, a sapphire substrate, a GaAs substrate, a SiC substrate, an alumina substrate, a ZnS substrate, a ZnO substrate, an LiMgO substrate, LiGaO₂ substrate, a MgAl₂O₄ substrate, and an InP substrate. Alternatively, the supporting substrate may also be formed of an insulating substrate formed of AlN or the like, a semiconductor substrate formed of Si, SiC, Ge, or the like, a metal substrate, or an alloy substrate. However, it is favorable to use a substrate having conductivity, or a metal substrate or an alloy substrate from viewpoints of mechanical characteristics, elastic deformation, plastic deformation, heat radiation property, and the like. Examples of the thickness of the supporting substrate include 0.05 mm to 0.5 mm. As the method of fixing the second light reflection layer to the supporting substrate, known methods such as a solder bonding method, a room-temperature bonding method, a bonding method using an adhesive tape, and a bonding method using wax bonding can be used. From a viewpoint of ensuring conductivity, it is favorable to employ a solder bonding method or a room-temperature bonding method. For example, in the case where a silicon semiconductor substrate that is a conductive substrate is used as the supporting substrate, it is desirable that a method in which bonding can be performed at a low temperature that is not more than 400° C. is employed to suppress warpage due to the difference of a thermal expansion coefficient. In the case where a GaN substrate is used as the supporting substrate, the bonding temperature may be not less than 400° C.

It is favorable that the first electrode has a single-layer configuration or a multilayer-configuration containing at least one kind of metal (including alloy) selected from the group consisting gold (Au), silver (Ag), palladium (Pd), platinum (Pt), nickel (Ni), Ti (titanium), vanadium (V), tungsten (W), chromium (Cr), Al (aluminum), Cu (copper), Zn (zinc), tin (Sn), and indium (In), for example. Specifically, for example, Ti/Au, Ti/Al, Ti/Al/Au, Ti/Pt/Au, Ni/Au, Ni/Au/Pt, Ni/Pt, Pd/Pt, and Ag/Pd can be exemplified. Note that the layer prior to “/” in the multiple-layer configuration is located closer to the active layer. The same applies in the following description. The first electrode can be deposited with a PVD method such as a vacuum evaporation method and a sputtering method.

Examples of the transparent conductive material forming the first electrode or the second electrode include an indium-tin oxide (ITO, Sn-doped In₂O₃, including crystalline ITO and amorphous ITO), an indium-zinc oxide (IZO), an indium-gallium oxide (IGO), an indium-doped gallium-zinc oxide (IGZO, In—GaZnO₄), IFO (F-doped In₂O₃), a tin oxide (SnO₂), ATO (Sb-doped SnO₂), FTO (F-doped SnO₂), and a zinc oxide (ZnO, including Al-doped ZnO and B-doped ZnO). Alternatively, examples of the second electrode include a transparent conductive film in which a gallium oxide, a titanium oxide, a niobium oxide, a nickel oxide, or the like is used as a base layer. Note that the material forming the second electrode is not limited to a transparent conductive material, and metal such as palladium (Pd), platinum (Pt), nickel (Ni), gold (Au), cobalt (Co), and rhodium (Rh) can be used although it depends on the arrangement state of the second light reflection layer and the second electrode. The second electrode only needs to be formed of at least one kind of these materials. The second electrode can be deposited with a PVD method such as a vacuum evaporation method and a sputtering method.

On the first electrode or the second electrode, a pad electrode may be provided to electrically connect to an external electrode or circuit. It is favorable that the pad electrode has a single-layer configuration or a multilayer-configuration containing at least one kind of metal selected from the group consisting of Ti (titanium), aluminum (Al), Pt (platinum), Au (gold), Ni (nickel), and Pd (palladium). Alternatively, the pad electrode may have a multilayer-configuration such as a multilayer-configuration of Ti/Pt/Au, a multilayer-configuration of Ti/Au, a multilayer-configuration of Ti/Pd/Au, a multilayer-configuration of Ti/Pd/Au, a multilayer-configuration of Ti/Ni/Au, a multilayer-configuration of Ti/Ni/Au/Cr/Au. In the case where the first electrode is formed of an Ag layer or an Ag/Pd layer, it is favorable that a cover metal layer formed of, for example, Ni/TiW/Pd/TiW/Ni is formed on the surface of the first electrode, and a pad electrode having, for example, a multiple-configuration of Ti/Ni/Au or a multiple-configuration of Ti/Ni/Au/Cr/Au is formed on the cover metal layer.

The light reflection layer (Distributed Bragg Reflector layer, DBR layer) or the selective growth mask layer is formed of, for example, a semiconductor multilayer film or a dielectric multilayer film. Examples of the dielectric material include an oxide, nitride (e.g., SiN_{X}, AlN_{X}, AlGaN, GaN_{X}, and BN_{X}), and fluoride of Si, Mg, Al, Hf, Nb, Zr, Sc, Ta, Ga, Zn, Y, B, Ti, and the like. Specifically, SiO_{X}, TiO_{X}, NbO_{X}, ZrO_{X}, TaO_{X}, ZnO_{X}, AlO_{X}, HfO_{X}, SiN_{X}, and AlN_{X} can be exemplified. Then, by alternately laminating two or more kinds of dielectric films formed of dielectric materials having a different refractive index of these dielectric materials, it is possible to obtain the light reflection layer or the selective growth mask layer. For example, a dielectric multilayer film such as SiO_{X}/SiN_{Y}, SiO_{X}/NbO_{Y}, SiO_{X}/ZrO_{Y}, and SiO_{X}/AlN_{Y} is favorable. In order to obtain a desired light reflectance, it only needs to appropriately select the material forming each dielectric film, the film thickness, the number of lamination, and the like. The thickness of each dielectric film can be appropriately adjusted by a material to be used and the like, and determined by the light emission wavelength λ₀ and the refractive index n of the material to be used in the light emission wavelength λ₀. Specifically, it is favorably odd number times of λ₀/(4n). For example, in the case where the light reflection layer or the selective growth mask layer is formed of SiO_{X}/NbO_{Y} in the light emitting device having the light emission wavelength λ₀ of 410 nm, approximately 40 nm to 70 nm can be exemplified. Examples of the number of lamination include two or more, and favorably, approximately 5 to 20. Examples of the whole thickness of the light reflection layer or the selective growth mask layer include approximately 0.6 μm to 1.7 μm.

Alternatively, the first light reflection layer desirably includes a dielectric film containing at least an N (nitrogen) atom. Furthermore, it is more desirable that the dielectric film containing an N atom is the uppermost layer of the dielectric multilayer film. Alternatively, the first light reflection layer is desirably covered with a dielectric material layer containing at least an N (nitrogen) atom. Alternatively, it is favorable that by performing nitridation on the surface of the first light reflection layer, the surface of the first light reflection layer is made to be a layer containing at least an N (nitrogen) atom (hereinafter, referred to as “surface layer” for convenience). It is favorable that the thickness of the dielectric film or the dielectric material layer containing at least an N atom, or the surface layer is odd number times of λ₀/(4n). Examples of the material forming the dielectric film or the dielectric material layer containing at least an N atom specifically include SiN_{X} and SiO_{X}N_{Z}. As described above, by forming the dielectric film or the dielectric material layer containing at least an N atom, or the surface layer, when the compound semiconductor layer covering the first light reflection layer is formed, it is possible to suppress the displacement between the crystal axis of the compound semiconductor layer covering the first light reflection layer and the crystal axis of the GaN substrate, and improve the quality of the laminated structure to be a resonator.

The light reflection layer or the selective growth mask layer can be formed on the basis of a well-known method. Examples of such a method specifically include a PVD method such as a vacuum evaporation method, a sputtering method, a reactive sputtering method, an ECR plasma sputtering method, a magnetron sputtering method, an ion beam assisted deposition method, an ion plating method, and a laser ablation method; various CVD methods; a coating method such as a spraying method, a spin coating method, and a dipping method; a method combining two or more of these methods; and a method of combining these methods and one or more of entire or partial pre-processing, application of an inert gas (Ar, He, Xe, etc.) or plasma, application of an oxygen gas, ozone gas, or plasma, oxidation processing (heat processing), and exposing processing.

Examples of the material forming the base layer include an oxide, nitride (e.g., SiN_{X}, AlN_{X}, AlGaN, GaN_{X}, and BN_{X}), and fluoride of Si, Mg, Al, Hf, Nb, Zr, Sc, Ta, Ga, Zn, Y, B, Ti, and the like. Specifically, for example, SiO_{X}, TiO_{X}, NbO_{X}, ZrO_{X}, TaO_{X}, ZnO_{X}, AlO_{X}, HfO_{X}, SiN_{X}, and AlN_{X} can be exemplified. Further, examples of the material forming a polishing stopper layer include an oxide, nitride (e.g., SiN_{X}, AlN_{X}, AlGaN, GaN_{X}, and BN_{X}), and fluoride of Si, Mg, Al, Hf, Nb, Zr, Sc, Ta, Ga, Zn, Y, B, Ti, and the like. Specifically, for example, SiO_{X}, TiO_{X}, NbO_{X}, ZrO_{X}, TaO_{X}, ZnO_{X}, AlO_{X}, HfO_{X}, SiN_{X}, and AlN_{X} can be exemplified. Examples of the method of polishing the first compound semiconductor layer include a chemical/mechanical polishing layer (CMP method). In the substrate having a concave portion and a convex portion, the concave portion and the convex portion can be provided by etching the surface of the substrate, for example.

The side surface or exposed surface of the laminated structure may be covered with an insulating film. Forming of the insulating film can be performed on the basis of a well-known method. The refractive index of the material forming the insulating film is favorably smaller than that of the material forming the laminated structure. Examples of the material forming the insulating film include a SiO_{X}-based material containing SiO₂, a SiN_{X}-based material, a SiO_{X}N_{Z}-based material, TaO_{X}, ZrO_{X}, AlN_{X}, AlO_{X}, and GaO_{X}. Alternatively, an organic material such as polyimide resin can be exemplified. Examples of the method of forming the insulating film include a PVD method such as a vacuum evaporation method and a sputtering method, and a CVD method. The insulating film can be formed on the basis of a coating method.

### Example 1

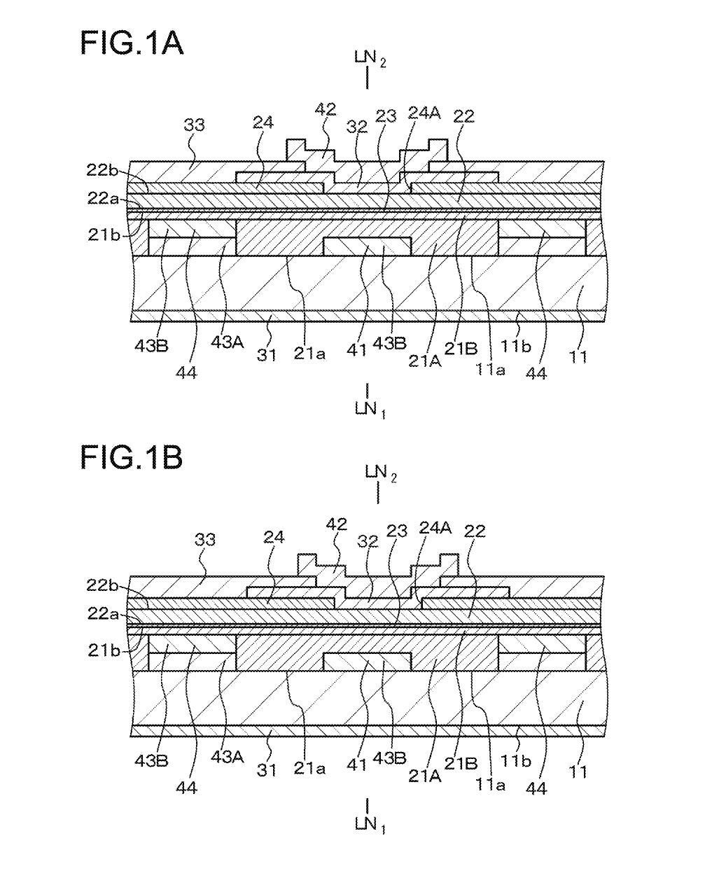

An example 1 relates to the light emitting device according to the first aspect of the present disclosure, specifically, the light emitting device having the first configuration and the method of manufacturing the light emitting device according to the present disclosure. A schematic partial cross-sectional view of the light emitting device in the example 1 is shown in FIG. 1A.

The light emitting device in the example 1 is specifically a surface emitting laser device (a vertical cavity laser, VCSEL), and includes

a selective growth mask layer 44,

a first light reflection layer 41 thinner than the selective growth mask layer 44,

a laminated structure including first compound semiconductor layers 21A and 21B formed on the first light reflection layer 41, an active layer 23, and a second compound semiconductor layer 22, and

a second electrode 32 formed on the second compound semiconductor layer 22, and a second light reflection layer 42. Then, the second light reflection layer 42 is opposed to the first light reflection layer 41.

Note that in the light emitting device in the example 1, the difference between the thickness of the selective growth mask layer 44 and the thickness of the first light reflection layer 41 (e.g., distance from the top surface of the selective growth mask layer 44 to the top surface of the first light reflection layer 41) is not less than 5×10⁻⁸ m, specifically, 100 nm. The top surface of the selective growth mask layer 44 is located closer to the active layer 23 than the top surface of the first light reflection layer 41.

Further, in the light emitting device in the example 1,

the first light reflection layer 41 includes a dielectric multilayer film 43B, and

the selective growth mask layer 44 includes the dielectric multilayer film 43B having the same configuration as that of a dielectric multilayer film constituting the first light reflection layer 41, and a base layer 43A, from the side of the active layer 23. Specifically, the layer composition and the number of layers of the dielectric multilayer film 43B constituting the first light reflection layer 41 are the same as those of the dielectric multilayer film 43B constituting the selective growth mask layer 44.

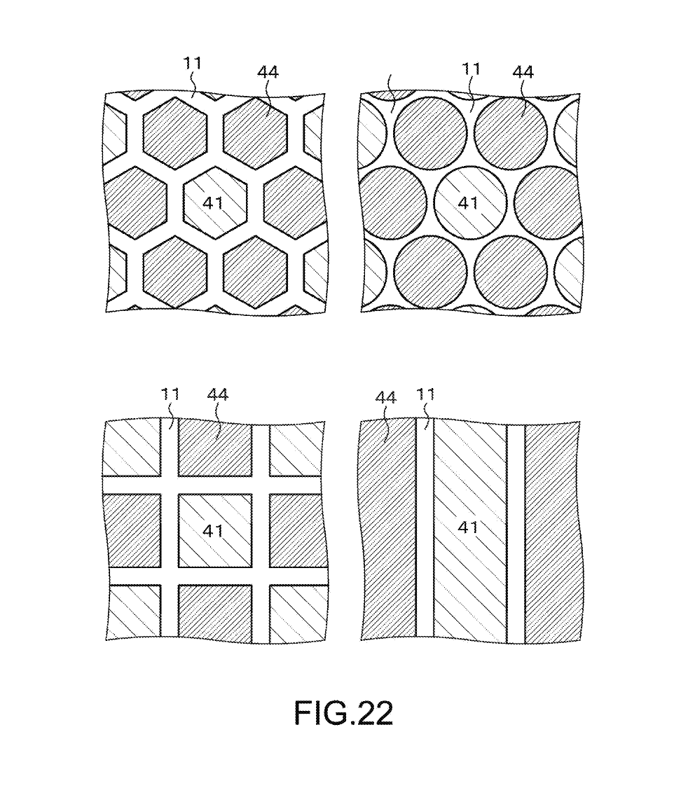

In the light emitting device in the example 1, the first light reflection layer 41 and the selective growth mask layer 44 are formed on a substrate (specifically, a GaN substrate) 11. Between the first light reflection layer 41 and the selective growth mask layer 44, a surface of the substrate 11 is exposed. Note that a plane orientation of a crystal surface of a surface 11a of the GaN substrate is [0001]. Specifically, on the (0001) surface (C surface) of the GaN substrate, the first light reflection layer 41 and the selective growth mask layer 44 are formed. As shown in a schematic plan view of FIG. 22, shapes of the first light reflection layer 41 and the selective growth mask layer 44 are each a regular hexagon. Note that in FIG. 22, different diagonal lines are added to the first light reflection layer 41 and the selective growth mask layer 44 to specifically display the first light reflection layer 41 and the selective growth mask layer 44. The regular hexagons are placed or arranged so that the compound semiconductor layer epitaxially grows in a lateral direction in a [11-20] direction or a direction crystallographically equivalent to this. Note that the shapes of the first light reflection layer 41 and the selective growth mask layer 44 are not limited thereto, and may each be a circular shape, a lattice shape, or a stripe shape.

Note that although the first compound semiconductor layers 21A and 21B, the active layer 23, and the second compound semiconductor layer 22 in the laminated structure are each formed of a GaN-based compound semiconductor, more specifically, the laminated structure is configured by laminating

the first compound semiconductor layer 21 (21A and 21B) that is formed of a GaN-based compound semiconductor and has a first surface 21a and a second surface 21b opposed to the first surface 21a,

the active layer (light emitting layer) 23 that is formed of a GaN-based compound semiconductor and in contact with the second surface 21b of the first compound semiconductor layer 21, and

the second compound semiconductor layer 22 that is formed of a GaN-based compound semiconductor and has a first surface 22a and a second surface 22b opposed to the first surface 22a, the first surface 22a being in contact with the active layer 23. Note that the first compound semiconductor layer includes a lower layer 21A of the first compound semiconductor layer and an upper layer 21B of the first compound semiconductor layer. Then, on the second surface 22b of the second compound semiconductor layer 22, the second electrode 32 and the second light reflection layer 42 formed of a dielectric multilayer film are formed. A first electrode 31 is formed on a different surface 11b of the substrate 11 opposed to the surface 11a of the substrate 11 on which the laminated structure is formed. The first light reflection layer 41 formed of a dielectric multilayer film is formed on the surface 11a of the substrate 11 and in contact with the first surface 21a of the first compound semiconductor layer 21. In some cases, it does not necessarily need to form the upper layer 21B of the first compound semiconductor layer.

Note that the light emitting device in the example 1 is formed of a surface emitting laser device that emits light from the top surface of the second compound semiconductor layer 22 via the second light reflection layer 42. Specifically, the light emitting device in the example 1 is a second-light-reflection-layer-emission-type light emitting device in which light is emitted from the second surface 22b of the second compound semiconductor layer 22 via the second light reflection layer 42. The substrate 11 remains to be left.

In the light emitting devices in the example 1 or examples 2 to 16 to be described later, between the second electrode 32 and the second compound semiconductor layer 22, a current constriction layer 24 formed of an insulating material such as SiO_{X}, SiN_{X}, and AlO_{X} is formed. An opening 24A is formed in the current constriction layer 24, and the second compound semiconductor layer 22 is exposed at the bottom of the opening 24A. The second electrode 32 is formed from the second surface 22b of the second compound semiconductor layer 22 over the current constriction layer 24, and the second light reflection layer 42 is formed on the second electrode 32. Furthermore, on the edge portion of the second electrode 32, a pad electrode 33 for electrically connecting an external electrode or circuit is connected. In the light emitting devices in the example 1 or examples 2 to 16 to be described later, the plane shape of the first light reflection layer 41 is a regular hexagon, and plane shapes of the second light reflection layer 42 and the opening 24A provided to the current constriction layer 24 are each a circular shape. Although the first light reflection layer 41 and the second light reflection layer 42 each have a multilayer structure, they are represented with a one layer to simplify the figure. It does not necessarily need to form the current constriction layer 24.

Then, in the light emitting device in the example 1, the distance from the first light reflection layer 41 to the second light reflection layer 42 is not less than 0.15 μm and not more than 50 μm, specifically, 4 μm, for example. Note that although a normal line of the first light reflection layer 41 that passes through the area centroid of the first light reflection layer 41 is represented by LN₁, and a normal line of the second light reflection layer 42 that passes through the area centroid of the second light reflection layer 42 is represented by LN₂, LN₁ and LN₂ match in the example shown in FIG. 1A.

The first compound semiconductor layer 21 is formed of an N-type GaN layer with a thickness of 4 μm, the active layer 23 with the total thickness of 180 nm is formed of a five-layer multiquantum well structure obtained by laminating an In_{0.04}Ga_{0.96}N layer (barrier layer) and an In_{0.16}Ga_{0.84}N layer (well layer), and

the second compound semiconductor layer 22 has a two-layer configuration of a p-type AlGaN electron barrier layer (with a thickness of 10 nm) and a p-type GaN layer. Note that the electron barrier layer is located on the side of the active layer. The first electrode 31 is formed of Ti/Pt/Au, the second electrode 32 is formed of a transparent conductive material, specifically, ITO, the pad electrode 33 is formed of Ti/Pd/Au or Ti/Pt/Au, and the first light reflection layer 41 and the second light reflection layer 42 are each formed of a laminated structure of an SiN_{X} layer and a SiO_{Y} layer (the total number of lamination of a dielectric multilayer film: 20 layers). The thickness of each layer is λ₀/(4n). The base layer 43A is specifically formed of SiO_{X}, TiO_{X}, NbO_{X}, ZrO_{X}, TaO_{X}, ZnO_{X}, AlO_{X}, HfO_{X}, SiN_{X}, AlN_{X}, or the like, and the thickness thereof is 100 nm. The thickness of the base layer 43A is equal to the difference between the thickness of the selective growth mask layer 44 and the thickness of the first light reflection layer 41.

In the light emitting device in the example 1, when the area of a part of the first light reflection layer 41 that is in contact with the first surface 21a of the first compound semiconductor layer 21 (a part of the first light reflection layer 41 opposed to the second light reflection layer 42) is represented by S₁ and the area of a part of the second light reflection layer 42 opposed to the second surface 22b of the second compound semiconductor layer 22 (a part of the second light reflection layer 42 opposed to the first light reflection layer 41) is represented by S₂, S₁ is smaller than S₂.

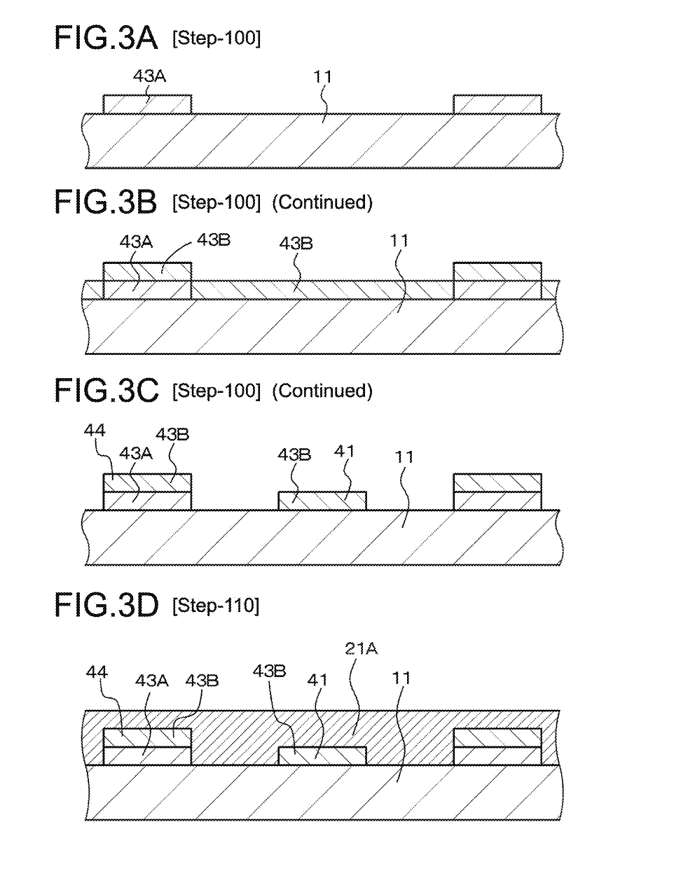

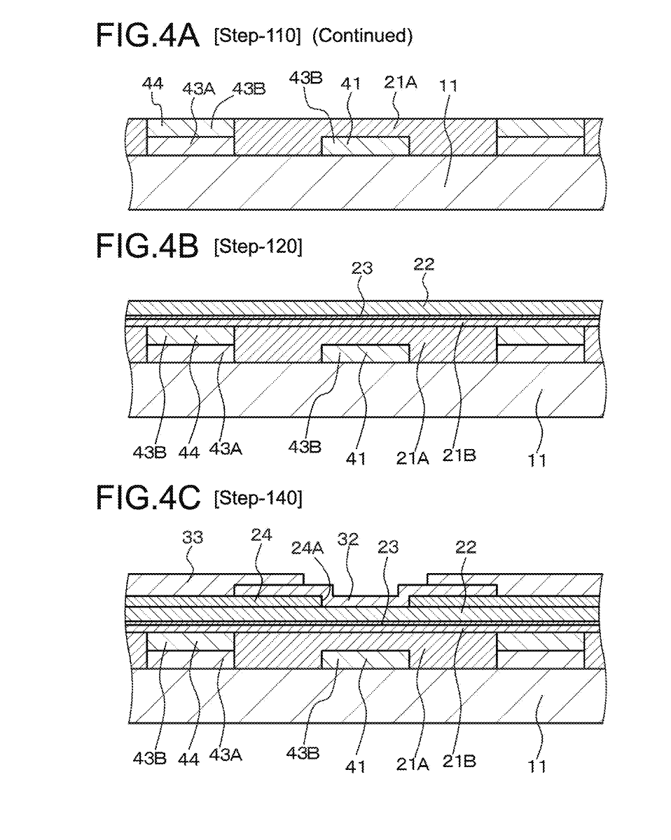

Hereinafter, on the basis of FIG. 3A, FIG. 3B, FIG. 3C, FIG. 4A, FIG. 4B, and FIG. 4C, which are each a schematic partial end view of a substrate and the like, a method of manufacturing the light emitting device in the example 1 will be described.

[Step-100]

On the substrate (specifically, GaN substrate) 11, the selective growth mask layer 44 and the first light reflection layer 41 are formed. Specifically, first, after forming the base layer 43A on an entire surface on the basis of a sputtering method, the base layer 43A is patterned on the basis of a photolithography technology and a dry etching technology, thereby leaving the base layer 43A in a region of the substrate 11 on which the selective growth mask layer 44 is to be formed (see FIG. 3A).

After that, the dielectric multilayer film 43B is conformally formed on an entire surface on the basis of a sputtering method (see FIG. 3B), the dielectric multilayer film 43B is patterned on the basis of a photolithography technology and a dry etching technology, and the substrate 11 is exposed by removing a part of the dielectric multilayer film 43B located between the region of the substrate 11 on which the selective growth mask layer 44 is to be formed and a region of the substrate 11 on which the first light reflection layer 41 is to be formed (see FIG. 3C).

[Step-110]

Next, after forming the first compound semiconductor layer on an entire surface, the first compound semiconductor layer is polished by using the selective growth mask layer 44 as a polishing stopper layer, thereby removing the first compound semiconductor layer on the selective growth mask layer 44 and leaving the first compound semiconductor layer on the first light reflection layer 41. Specifically, the lower layer 21A of the first compound semiconductor layer formed of an n-type GaN is formed on an entire surface on the basis of an MOCVD method (using a TMG gas and an SiH₄ gas) for epitaxial growth in a lateral direction, such as an ELO method (see FIG. 3D). After that, the lower layer 21A of the first compound semiconductor layer is polished by using the selective growth mask layer 44 as a polishing stopper layer on the basis of a chemical/mechanical polishing method (CMP method), thereby removing the lower layer 21A on the selective growth mask layer 44 and leaving the lower layer 21A on the first light reflection layer 41 (see FIG. 4A).

[Step-120]

Next, the active layer 23 and the second compound semiconductor layer 22 are formed on an entire surface. Specifically, in the example 1, the upper layer 21B of the first compound semiconductor layer, the active layer 23, and the second compound semiconductor layer 22 are formed on an entire surface on the basis of an MOCVD method. More specifically, the upper layer 21B of the first compound semiconductor layer formed of n-type GaN is formed on the basis of an epitaxial growth method, and the active layer 23 is formed on the upper layer 21B of the first compound semiconductor layer by using a TMG gas and a TMI gas. After that, an electron barrier layer is formed by using a TMG gas, a TMA gas, and a Cp₂Mg gas, a p-type GaN layer is formed by using a TMG gas and a Cp₂Mg gas, and thus, the second compound semiconductor layer 22 is obtained. By the steps described above, the laminated structure can be obtained. Specifically, on the substrate (specifically, GaN substrate) 11 including the first light reflection layer 41, a laminated structure configured by laminating

the first compound semiconductor layer 21 (21A and 21B) that is formed of a GaN-based compound semiconductor and has the first surface 21a and the second surface 21b opposed to the first surface 21a,

the active layer 23 that is formed of a GaN-based compound semiconductor and in contact with the second surface 21b of the first compound semiconductor layer 21, and

the second compound semiconductor layer 22 that is formed of a GaN-based compound semiconductor and has the first surface 22a and the second surface 22b opposed to the first surface 22a, the first surface 22a being in contact with the active layer 23,

is caused to epitaxially grow. Further, on the selective growth mask layer 44, a laminated structure configured by laminating

the upper layer 21B of the first compound semiconductor layer formed of a GaN-based compound semiconductor,

the active layer 23 that is formed of a GaN-based compound semiconductor and in contact with the upper layer 21B of the first compound semiconductor layer, and

the second compound semiconductor layer 22 that is formed of a GaN-based compound semiconductor and has the first surface 22a and the second surface 22b opposed to the first surface 22a, the first surface 22a being in contact with the active layer 23,

is caused to epitaxially grow. Thus, the structure shown in FIG. 4B can be obtained.

[Step-130]

Next, on the second surface 22b of the second compound semiconductor layer 22, the current constriction layer 24 that is formed of an insulating material with a thickness of 0.2 μm and has the opening 24A is formed on the basis of a well-known method.

[Step-140]

After that, on the second compound semiconductor layer 22, the second electrode and the second light reflection layer opposed to the first light reflection layer 41 are formed. Specifically, on the second surface 22b of the second compound semiconductor layer 22, the second electrode 32 and the second light reflection layer 42 formed of a dielectric multilayer film are formed. More specifically, the second electrode 32 formed of ITO with a thickness of 50 nm is formed from the second surface 22b of the second compound semiconductor layer 22 over the current constriction layer 24 on the basis of, for example, a lift-off method, and the pad electrode 33 is formed from the second electrode 32 over the current constriction layer 24 on the basis of a well-known method. Thus, the structure shown in FIG. 4C can be obtained. After that, the second light reflection layer 42 is formed from the second electrode 32 over the pad electrode 33 on the basis of a well-known method. On the other hand, on the different surface 11b of the substrate 11, the first electrode 31 is formed on a well-known method. Thus, the light emitting device in the example 1 having the structure shown in FIG. 1A can be obtained. Note that it does not necessary need to form the second light reflection layer 42 on the upper side of the selective growth mask layer 44.

[Step-150]

After that, the light emitting device is separated by performing so-called device separation, and the side surface or exposed surface of the laminated structure is covered with an insulating film formed of SiO_{X}, for example. Then, in order to connect the first electrode 31 and the pad electrode 33 to an external circuit or the like, a terminal and the like are formed on the basis of a well-known method, they are packaged or sealed, and thus, the light emitting device in the example 1 is completed.

In the light emitting device in the example 1, the selective growth mask layer and the first light reflection layer thinner than the selective growth mask layer are provided. Specifically, because a region having the selective growth mask layer does not constitute a light emission area of the light emitting device and it only needs to reduce the thickness of the first compound semiconductor layer formed on the first light reflection layer by using the selective growth mask layer as a polishing stopper layer on the basis of a polishing method, it is possible to reduce the thickness of the first compound semiconductor layer with high precision. Further, in the method of manufacturing the light emitting device in the example 1, after forming the selective growth mask layer and the first light reflection layer, the first compound semiconductor layer is formed, and then, the first compound semiconductor layer is polished by using the selective growth mask layer as a polishing stopper layer, thereby removing the first compound semiconductor layer on the selective growth mask layer and leaving the first compound semiconductor layer on the first light reflection layer. Therefore, it is possible to reduce the thickness of the first compound semiconductor layer with high precision.

As described above, when the first compound semiconductor layer 21 is formed by lateral direction growth on the basis of a method of lateral direction epitaxial growth such as an ELO method on the substrate 11 on which the first light reflection layer 41 and the selective growth mask layer 44 are formed, and the first compound semiconductor layer 21 that epitaxially grows from the edge portion of the first light reflection layer 41 to the center portion of the first light reflection layer 41 is associated, many crystal defects are caused in the associated portion in some cases.

In the light emitting device in a modified example of the example 1, as shown in FIG. 1B, there is no area centroid of the second light reflection layer 42 on the normal line LN₁ of the first light reflection layer 41 that passes through the area centroid of the first light reflection layer 41. The normal line LN₂ of the second light reflection layer 42 that passes through the area centroid of the second light reflection layer 42 and the normal line of the active layer 23 that passes through the area centroid of the active layer 23 (specifically, the area centroid of the active layer 23 constituting the device region) match. Alternatively, there is no area centroid of the active layer 23 on the normal line LN₁ of the first light reflection layer 41 that passes through the area centroid of the first light reflection layer 41. Accordingly, the associated portion (specifically, located on the normal line LN₁ or close thereto) where there are many crystal defects is not located on the center portion of the device region, characteristics of the light emitting device are not adversely affected, or characteristics of the light emitting device are less adversely affected. Note that when the area of a part of the first light reflection layer 41 that is in contact with the first surface 21a of the first compound semiconductor layer 21 (a part of the first light reflection layer 41 opposed to the second light reflection layer 42), which constitutes the device region, is represented by S₃ and the area of a part of the second light reflection layer 42 opposed to the second surface 22b of the second compound semiconductor layer 22 (a part of the second light reflection layer 42 opposed to the first light reflection layer 41), which constitutes the device region, is represented by S₄, S₃ is smaller than S₄.

Further, in the surface emitting laser device, a mode where the optical field intensity at the center of a resonator is strongest, i.e., a basic mode, is most stable in many cases. By causing the normal line LN₂ and the normal line LN₂ not to match or allowing no area centroid of the active layer 23 to be on the normal lien LN₂, in other words, by intentionally displacing the device region (current injection region) and the central axis of the first compound semiconductor layer 21, it is possible to reduce the optical field intensity in the central axis of the resonator and reduce the stability of the basic mode. Accordingly, it is possible to reduce the stability of the basis mode at the time of high-power operation, cause a kink, and reduce the upper limit of the optical output of the surface emitting laser device. Therefore, in the case where it is used for application where the upper limit of output is desired to be restricted such as application of laser light to a living body, for example, it is favorable to employ such a configuration. Assuming that the plane shape of the device region is a circular shape, when the diameter thereof is represented by R₀, examples of the shift amount between the normal line LN₂ and the normal line LN₂ include 0.01R₀ to 0.25R₀.

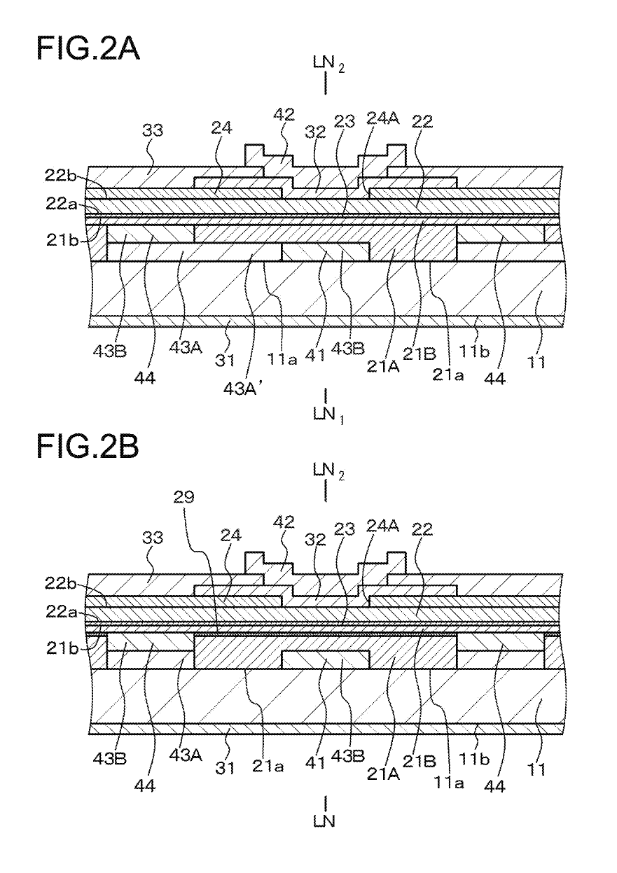

Further, as shown in FIG. 2A, a structure where a part 43A′ of the base layer 43A and a part of the first light reflection layer 41 are in contact with each other may be provided.

In [Step-110], the lower layer 21A of the first compound semiconductor layer is polished by using the selective growth mask layer 44 as a polishing stopper layer on the basis of a chemical/mechanical polishing method (CMP method), thereby removing the lower layer 21A of the first compound semiconductor layer on the selective growth mask layer 44 and leaving the lower layer 21A of the first compound semiconductor layer on the first light reflection layer 41. However, an impurity-containing compound semiconductor layer 29 is formed on the top surface of the lower layer 21A of the first compound semiconductor layer, depending on the kind of the slurry used when polishing is performed on the basis of the CMP method. Specifically, when such a light emitting device is expressed in accordance with a light emitting device according to a second aspect of the present disclosure, as shown in a schematic partial cross-sectional view of FIG. 2, it includes

the first light reflection layer 41,

the laminated structure including the first compound semiconductor layer 21 formed on the first light reflection layer 41, the active layer 23, and the second compound semiconductor layer 22,

the second electrode 32 formed on the second compound semiconductor layer 22, and the second light reflection layer 42, and

the first electrode 31,

the second light reflection layer 42 is opposed to the first light reflection layer 41, and

the impurity-containing compound semiconductor layer 29 is formed on the laminated structure. Note that the impurity concentration of the impurity-containing compound semiconductor layer 29 is not less than 10 times, specifically, approximately 15 times, the impurity concentration in the compound semiconductor layer adjacent to the impurity-containing compound semiconductor layer 29 (specifically, the lower layer 21A and the upper layer 21B of the first compound semiconductor layer). Further, the impurity concentration of the impurity-containing compound semiconductor layer 29 is not less than 1×10¹⁷/cm³, specifically, 1.5×10¹⁸/cm³. Further, the impurity contained in the impurity-containing compound semiconductor layer 29 includes at least one kind of element selected from the group consisting of boron (B), potassium (K), calcium (Ca), sodium (Na), silicon (Si), aluminum (Al), oxygen (O), carbon (C), sulfur (S), halogen (chlorine (Cl) or fluorine (F)), and heavy metal (chromium (Cr), etc.). Specifically, when the impurity-containing compound semiconductor layer 29 is analyzed on the basis of secondary ion mass spectrometry (SIMS), it has been found that aluminum (Al), oxygen (O), chlorine (Cl), and sulfur (S) are contained. Note that the impurity-containing compound semiconductor layer 29 can be formed also in light emitting devices in the various examples described below. Specifically, the light emitting device according to the second aspect of the present disclosure can be applied also to light emitting devices in the various examples described below.

### Example 2

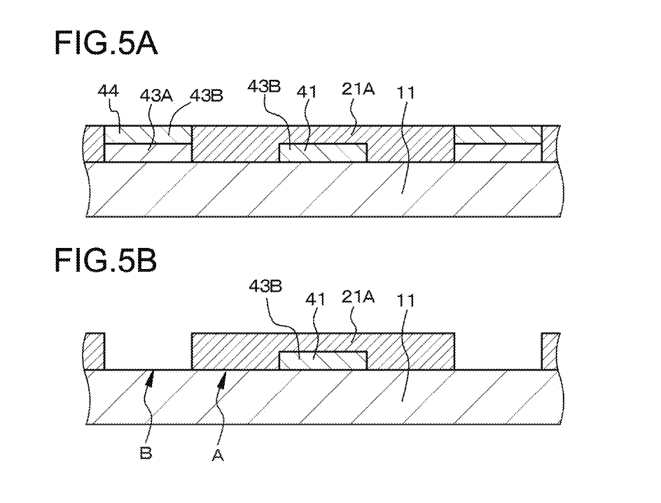

An example 2 is modification of the method of manufacturing the light emitting device in the example 1. In a method of manufacturing the light emitting device in the example 2, after [step-110] in the method of manufacturing the light emitting device in the example 1 is finished (see FIG. 5A), the selective growth mask layer 44 is removed before [step-120] is performed (see FIG. 5B). The removal of the selective growth mask layer 44 can be performed on the basis of a photolithography technology and a dry etching technology.

Other than the above, because the method of manufacturing the light emitting device in the example 2 can be substantially the same as the method of manufacturing the light emitting device described in the example 1, detailed description thereof is omitted. Because the configuration of the obtained light emitting device can be substantially the same as that of the light emitting device described in the example 1 other than that there is no selective growth mask layer 44, detailed description thereof is omitted. Note that there is a difference between a region “A” (region in which the lower layer 21A of the first compound semiconductor layer is formed) and a region “B” (region in which the selective growth mask layer 44 is removed) in FIG. 5B that the threading dislocation density of the compound semiconductor layer formed on the region A is higher than that on the region B.

### Example 3

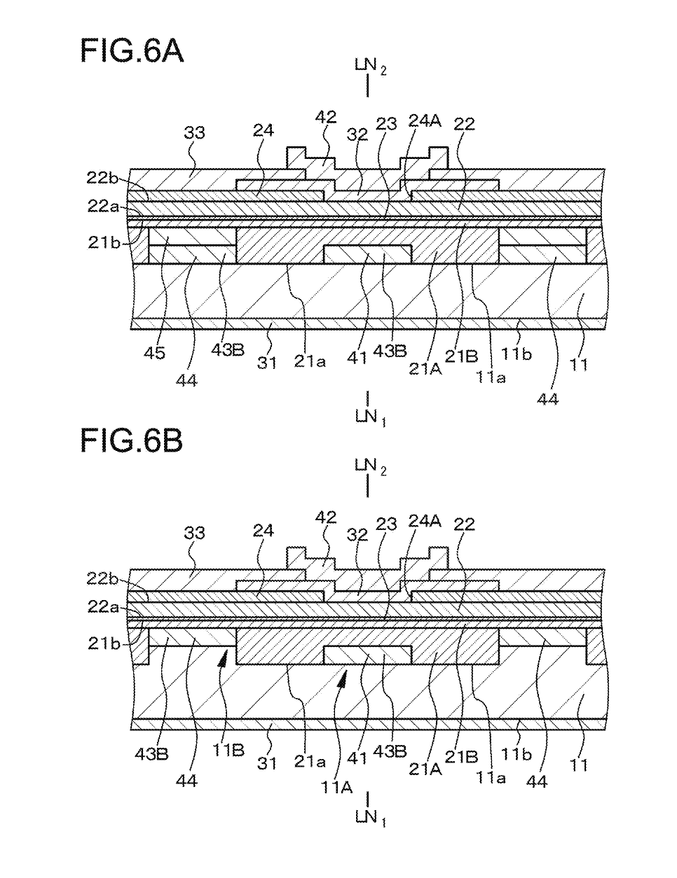

An example 3 is modification of the light emitting device in the example 1, but relates to the light emitting device having the second configuration. As shown in a schematic partial cross-sectional view of FIG. 6A, in a light emitting device in the example 3,

the first light reflection layer 41 includes the dielectric multilayer film 43B, and

the selective growth mask layer 44 includes a polishing stopper layer 45 and the dielectric multilayer film 43B having the same configuration as that of the dielectric multilayer film 43B constituting the first light reflection layer 41 from the side of the active layer 23. Specifically, the layer composition and the number of layers of the dielectric multilayer film 43B constituting the first light reflection layer 41 are the same as those of the dielectric multilayer film 43B constituting the selective growth mask layer 44. The polishing stopper layer 45 with a thickness of 100 nm is formed of SiO_{X}, TiO_{X}, NbO_{X}, ZrO_{X}, TaO_{X}, ZnO_{X}, AlO_{X}, HfO_{X}, SiN_{X}, AlN_{X}, or the like.

In a method of manufacturing a light emitting device in the example 3, in a step similar to [step-100] in the method of manufacturing the light emitting device in the example 1, first, the dielectric multilayer film 43B is formed on the substrate (GaN substrate) 11 on the basis of a sputtering method. Next, after forming the polishing stopper layer 45 on an entire surface on the basis of a sputtering method, the polishing stopper layer 45 is patterned on the basis of a photolithography technology and a dry etching technology, thereby leaving the polishing stopper layer 45 in a region of the dielectric multilayer film 43B on which the selective growth mask layer 44 is to be formed. Further, it only needs to remove a part of the dielectric multilayer film 43B located between a region of the substrate 11 on which the selective growth mask layer 44 is to be formed and a region of the substrate 11 on which the first light reflection layer 41 is to be formed. Other than the above, because the method of manufacturing the light emitting device in the example 3 can be substantially the same as the method of manufacturing the light emitting device described in the example 1, detailed description thereof is omitted. Because the configuration of the obtained light emitting device can be substantially the same as that of the light emitting device described in the example 1 other than the above, detailed description thereof is omitted.

### Example 4

Also the example 4 is modification of the light emitting device in the example 1, but relates to the light emitting device having the third configuration. As shown in a schematic partial cross-sectional view of FIG. 6B, in a light emitting device in the example 4,

the selective growth mask layer 44 and the first light reflection layer 41 are formed on the substrate 11,

the substrate 11 includes a concave portion 11A and a convex portion 11B,

the selective growth mask layer 44 is formed on the convex portion 11B of the substrate 11, and

the first light reflection layer 41 is formed on the concave portion 11A of the substrate 11. Note that the selective growth mask layer 44 includes the dielectric multilayer film 43B having the same configuration as that of the dielectric multilayer film 43B constituting the first light reflection layer 41. Specifically, the layer composition and the number of layers of the dielectric multilayer film 43B constituting the first light reflection layer 41 are the same as those of the dielectric multilayer film 43B constituting the selective growth mask layer 44. The concave portion 11A and the convex portion 11B in the substrate 11 can be provided by etching the surface of the substrate 11, for example.

In the method of manufacturing the light emitting device in the example 4, in a step similar to [step-100] in the method of manufacturing the light emitting device in the example 1, first, the concave portion 11A and the convex portion 11B are provided to the substrate 11 by etching the surface of the substrate 11. Next, the dielectric multilayer film 43B is conformally formed on an entire surface on the basis of a sputtering method. Then, by patterning the dielectric multilayer film 43B on the basis of a photolithography technology and a dry etching technology, it only needs to leave the dielectric multilayer film 43B in a region in which the selective growth mask layer 44 is to be formed and a region in which the first light reflection layer 41 is to be formed. Other than the above, because the method of manufacturing the light emitting device in the example 4 can be substantially the same as the method of manufacturing the light emitting device described in the example 1, detailed description thereof is omitted. Because the configuration of the obtained light emitting device can be substantially the same as that of the light emitting device described in the example 1 other than the above, detailed description thereof is omitted.

### Example 5

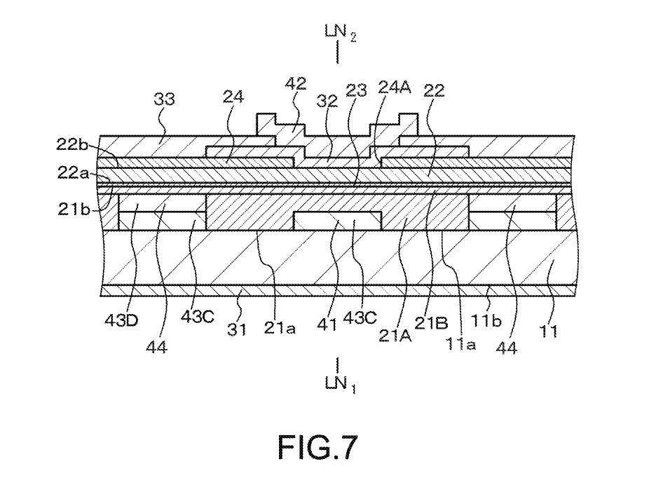

Also an example 5 is modification of the light emitting device in the example 1, but relates to the light emitting device having the fourth configuration. As shown in a schematic partial cross-sectional view of FIG. 7, in a light emitting device in the example 5, the selective growth mask layer 44 includes dielectric multilayer films 43C and 43D with a thickness different from that of the dielectric multilayer film 43C constituting the first light reflection layer 41. Specifically, the number of layers of the dielectric multilayer film 43C and 43D constituting the selective growth mask layer 44 is different from that of the dielectric multilayer film 43C constituting the first light reflection layer 41.

In the method of manufacturing the light emitting device in the example 5, in a step similar to [step-100] in the method of manufacturing the light emitting device in the example 1, first, the dielectric multilayer film 44C for forming the first light reflection layer 41 is formed on an entire surface of the substrate 11 on the basis of a sputtering method. Next, a part of the dielectric multilayer film 43C for forming the first light reflection layer 41 is covered, the dielectric multilayer film 43D is formed on an entire surface on the basis of a sputtering method, and thus, the dielectric multilayer films 43 and 43D constituting the selective growth mask layer 44 are obtained. After that, by successively patterning the dielectric multilayer film 43D and the dielectric multilayer film 43C on the basis of a photolithography technology and a dry etching technology, it only needs to leave the dielectric multilayer films 43C and 43D in a region in which the selective growth mask layer 44 is to be formed and leave the dielectric multilayer film 43C in a region in which the first light reflection layer 41 is to be formed. Other than the above, because the method of manufacturing the light emitting device in the example 5 can be substantially the same as the method of manufacturing the light emitting device described in the example 1, detailed description thereof is omitted. Because the configuration of the obtained light emitting device can be substantially the same as that of the light emitting device described in the example 1 other than the above, detailed description thereof is omitted.

### Example 6

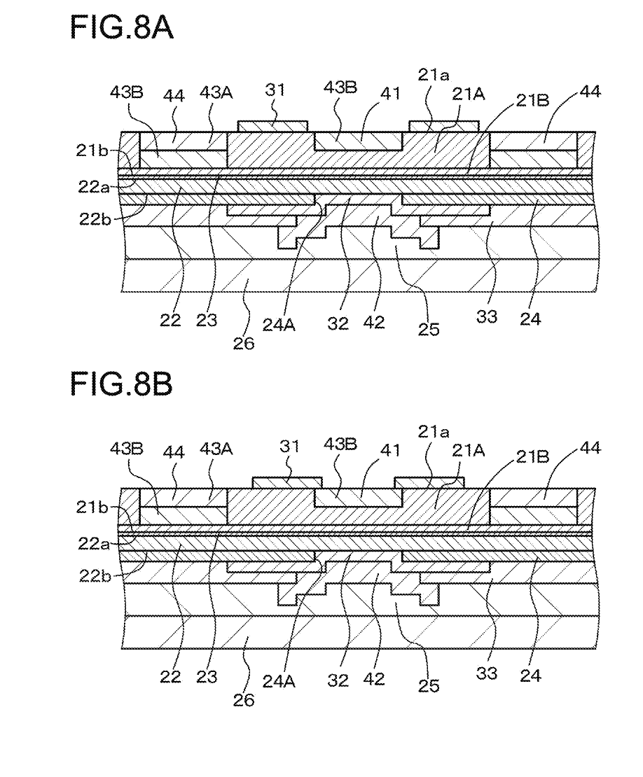

An example 6 is modification of the examples 1 to 5. As shown in a schematic partial cross-sectional view of FIG. 8A, in the light emitting device in the example 6, light generated in the active layer 23 is emitted from the top surface of the first compound semiconductor layer 21 to the outside via the first light reflection layer 41. Specifically, the light emitting device in the example 6 is a first-light-reflection-layer-emission-type surface emitting laser device. Then, in the light emitting device in the example 6, the second light reflection layer 42 is fixed to a supporting substrate 26 formed of a silicon semiconductor substrate via a joint layer 25 including a gold (Au) layer or a solder layer containing tin (Sn) on the basis of a solder joint method. Note that in the light emitting device in the example 6 shown in FIG. 8A is a modified example of the light emitting device in the example 1.

In the example 6, the active layer 23, the second compound semiconductor layer 22, the second electrode 32, and the second light reflection layer 42 are successively formed on the first compound semiconductor layer 21, and then, the second light reflection layer 42 is fixed to the supporting substrate 26. After that, the substrate 11 is removed by using the first light reflection layer 41 and the selective growth mask layer 44 as polishing stopper layers to expose the first compound semiconductor layer 21 (the first surface 21a of the first compound semiconductor layer 21), the first light reflection layer 41, and the selective growth mask layer 44. Then, the first electrode 31 is formed on the first compound semiconductor layer 21 (the first surface 21a of the first compound semiconductor layer 21).

The distance from the first light reflection layer 41 to the second light reflection layer 42 is not less than 0.15 μm and not more than 50 μm, and specifically, 4 μm, for example. In the light emitting device in the example 6, the first light reflection layer 41 and the first electrode 31 are separated from each other, i.e., they have an offset. The separation distance is not more than 1 mm, specifically, 0.05 mm on average, for example.

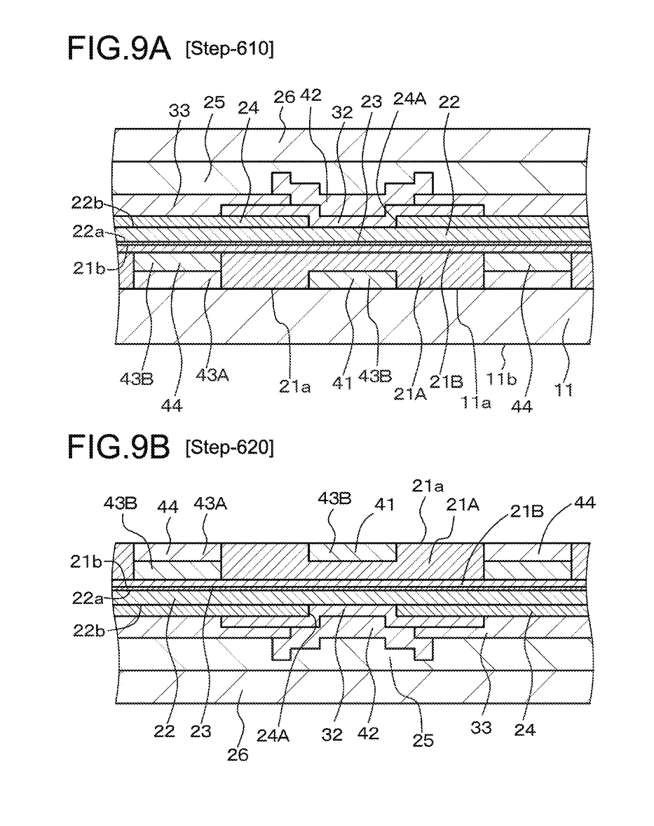

Hereinafter, a method of manufacturing the light emitting device in the example 6 will be described with reference to FIG. 9A and FIG. 9B, which are each a schematic partial end view of a laminates structure and the like.

[Step-600]

First, by performing steps similar to [step-100] to [step-140] in the example 1, the structure shown in FIG. 1A is obtained. Note that the first electrode 31 is not formed.

[Step-610]

After that, the second light reflection layer 42 is fixed to the supporting substrate 26 via the joint layer 25. Thus, the structure shown in FIG. 9A can be obtained.

[Step-620]

Next, the substrate (GaN substrate) 11 is removed to expose the first surface 21a of the first compound semiconductor layer 21, the first light reflection layer 41, and the selective growth mask layer 44. Specifically, first, the thickness of the substrate 11 is reduced on the basis of a mechanical polishing method, and then, the remaining part of the substrate 11 is removed on the basis of a CMP method. Thus, the first surface 21a of the first compound semiconductor layer 21, the first light reflection layer 41, and the selective growth mask layer 44 can be exposed, and the structure shown in FIG. 9B can be obtained.

[Step-630]

After that, on the first surface 21a of the first compound semiconductor layer 21, the first electrode 31 is formed on the basis of a well-known method. Thus, it is possible to obtain the light emitting device in the example 6 having the structure shown in FIG. 8A.

[Step-640]

After that, the light emitting device is separated by performing so-called device separation, and the side surface or exposed surface of the laminated structure is covered with an insulating film formed of SiO_{X}, for example. Then, in order to connect the first electrode 31 and the pad electrode 33 to an external circuit or the like, a terminal and the like are formed on a well-known method, they are packaged or sealed, and thus, the light emitting device in the example 6 is completed.

In the method of manufacturing the light emitting device in the example 6, the substrate is removed in the state where the first light reflection layer and the selective growth mask layer are formed. Therefore, as a result of causing the first light reflection layer and the selective growth mask layer to function as polishing stopper layers at the time when the substrate is removed, it is possible to reduce the variability of removal of the substrate in the substrate plane and then the variability of the thickness of the first compound semiconductor layer and make the length of a resonator uniform. As a result, it is possible to achieve the stability of characteristics of the obtained light emitting device. Furthermore, because the surface (flat surface) of the first compound semiconductor layer on the interface between the first light reflection layer and the first compound semiconductor layer is flat, it is possible to minimize scattering of light on the flat surface.

In the example of the light emitting device shown in FIG. 8A, the end portion of the first electrode 31 is separated from the first light reflection layer 41. Meanwhile, in the example of the light emitting device shown in FIG. 8B, the end portion of the first electrode 31 extends to the outer periphery of the first light reflection layer 41. Alternatively, the first electrode may be formed so that the end portion of the first electrode is in contact with the first light reflection layer.

### Example 7

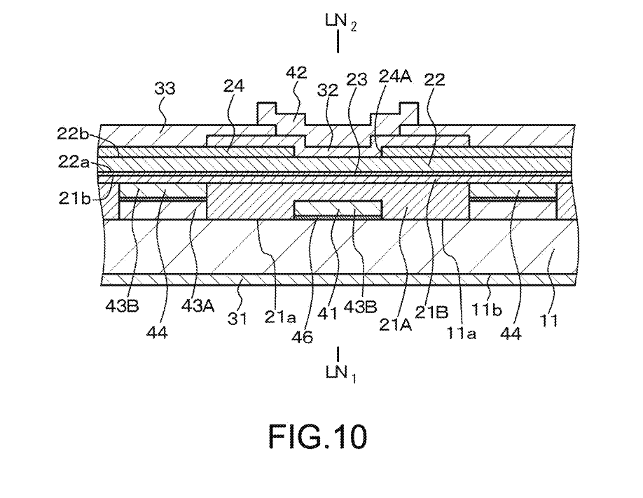

An example 7 is modification of the examples 1 to 6, but relates to the light emitting devices having the fifth and sixth configuration and the like. A schematic partial cross-sectional view of a light emitting device in the example 7 is shown in FIG. 10. In the light emitting device in the example 7, the off-angle of a plane orientation of a crystal surface of the surface 11a of the GaN substrate 11 is not more than 0.4 degrees, favorably, not more than 0.40 degrees. When the area of the GaN substrate 11 is represented by S₀, the total area of the first light reflection layer 41 and the selective growth mask layer 44 is not more than 0.8S₀. Examples of the lower limit value of the total area of the first light reflection layer 41 and the selective growth mask layer 44 include, but not limited to, 0.004×S₀. Then, a thermal expansion relaxation film 46 is formed on the GaN substrate 11 as the lowermost layer of the first light reflection layer 41 (the light emitting device having the fifth configuration), and a linear thermal expansion coefficient CTE of the lowermost layer of the first light reflection layer 41 that is in contact with the GaN substrate 11 (to which the thermal expansion relaxation film 46 corresponds) satisfies the following relationship,

1×10⁻⁶/K≦CTE≦1×10⁻⁵/K, and

favorably,

1×10⁻⁶/K<CTE≦1×10⁻⁵

(the light emitting device having the sixth configuration).

Specifically, the thermal expansion relaxation film 46 (the lowermost layer of the first light reflection layer 41) is formed of, for example, silicon nitride (SiN_{X}) that satisfies the following relationship,

t₁=λ₀/(2n₁).

Note that the thermal expansion relaxation film 46 (the lowermost layer of the first light reflection layer 41) with such a film thickness is transparent for light having a wavelength λ0, and does not have a function as a light reflection layer. The CTE values of silicon nitride (SiN_{X}) and the GaN substrate 11 are as shown in the following Table 1. The CTE values are each a value at 25° C.

TABLE 1

| | |
|---|---|
| GaN substrate: | 5.59 × 10⁻⁶/K |
| Silicon nitride (SiNX): | 2.6~3.5 × 10⁻⁶/K |

In manufacturing the light emitting device in the example 7, first, the base layer 43A is formed in a step similar to [step-100] in the example 1, thereby leaving the base layer 43A in a region in which the selective growth mask layer 44 is to be formed. After that, the thermal expansion relaxation film 46 constituting the lowermost layer of the first light reflection layer 41 is formed, and the remaining part of the first light reflection layer 41 formed of a dielectric multilayer film is formed on the thermal expansion relaxation film 46. Then, by performing patterning, the first light reflection layer 41 is obtained. After that, it only needs to perform steps similar to [step-110] to [step-150] in the example 1.

In the example 7, the relationship between an off-angle and a surface roughness Ra of the second compound semiconductor layer 22 has been examined. The results are shown in the following Table 2. From Table 2, it can be seen that the value of the surface roughness Ra of the second compound semiconductor layer 22 is large when the off-angle exceeds 0.4 degrees. Specifically, by making the off-angle not more than 0.4 degrees, favorably, 0.40 degrees, it is possible to reduce step bunching during growth of the compound semiconductor layer, and reduce the value of the surface roughness Ra of the second compound semiconductor layer 22. As a result, it is possible to obtain the second light reflection layer 42 having excellent smoothness, and variability of characteristics such as a light reflectance is unlikely to occur.

TABLE 2

| Off-angle (degrees) | Surface roughness Ra (nm) |
|---|---|
| 0.35 | 0.87 |
| 0.38 | 0.95 |
| 0.43 | 1.32 |
| 0.45 | 1.55 |
| 0.50 | 2.30 |

Further, the relationship between the area S₀ of the GaN substrate 11, the total area of the first light reflection layer 41 and the selective growth mask layer 44, and the surface roughness Ra of the second compound semiconductor layer 22 has been examined. The results are shown in the following Table 3. From Table 3, it has been found that the value of the surface roughness Ra of the second compound semiconductor layer 22 can be reduced by making the total area of the first light reflection layer 41 and the selective growth mask layer 44 not more than 0.8S₀.

TABLE 3

| Total area | Surface roughness Ra (nm) |
|---|---|
| 0.88S₀ | 1.12 |
| 0.83S₀ | 1.05 |
| 0.75S₀ | 0.97 |
| 0.69S₀ | 0.91 |
| 0.63S₀ | 0.85 |

From the above results, it can be seen that the surface roughness Ra of the second compound semiconductor layer (the second surface 22b of the second compound semiconductor layer 22) is favorably not more than 1.0 nm.

Furthermore, when a light emitting device having a configuration and structure similar to those of the example 7 except in that the thermal expansion relaxation film 46 is not formed and the lowermost layer of the first light reflection layer 41 is formed of SiO_{X} (CTE: 0.51 to 0.58×10⁻⁶/K) is manufactured, the first light reflection layer 41 is peeled from the GaN substrate 11 during deposition of the laminated structure in some cases depending on the manufacturing conditions. Meanwhile, in the example 7, the first light reflection layer 41 is not peeled from the GaN substrate 11 during deposition of the laminated structure.

As described above, in the light emitting device in the example 7 and the method of manufacturing the same, it is possible to reduce the surface roughness of the second compound semiconductor layer because the off-angle of the plane orientation of the crystal surface of the surface of the GaN substrate and the proportion of the total area of the first light reflection layer and the selective growth mask layer are specified. Specifically, it is possible to form the second compound semiconductor layer having excellent surface morphology. As a result, it is possible to obtain the second light reflection layer having excellent smoothness. Therefore, a desired light reflectance can be obtained, and the variability of characteristics of the light emitting device is unlikely to occur. Furthermore, since a thermal expansion relaxation film is formed or the CTE value is specified, it is possible to prevent such a problem that the first light reflection layer is peeled from the GaN substrate due to the difference between a linear thermal expansion coefficient of the GaN substrate and a linear thermal expansion coefficient of the first light reflection layer from occurring, and provide a light emitting device having high reliability. Furthermore, since the GaN substrate is used, a dislocation is unlikely to occur in the compound semiconductor layer, and it is possible to prevent such a problem that the thermal resistance of light emitting device is increased from occurring. As a result, it is possible to give high reliability to the light emitting device and provide the first electrode (n-side electrode) on the side (back surface side) different from the side of the second electrode (p-side electrode), with the GaN substrate as a reference.

### Example 8

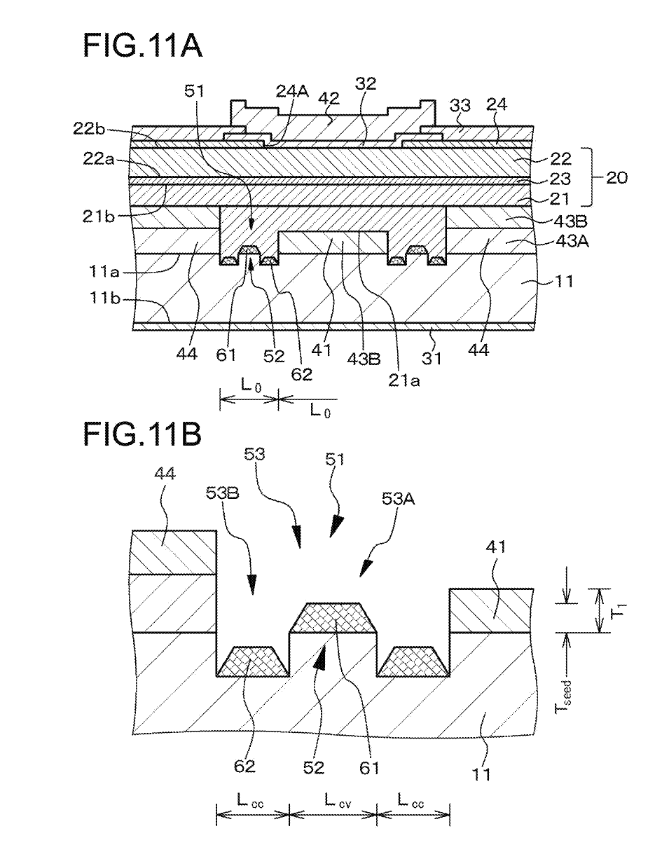

An example 8 is modification of the examples 1 to 7, but relates to the light emitting device having the seventh configuration, and more specifically, to the light emitting device having the 7-A-th configuration. A schematic partial cross-sectional view of a light emitting device in the example 8 is shown in FIG. 11A, and a schematic partial end view obtained by enlarging a surface of a part of a substrate (GaN substrate) adjacent to the first light reflection layer, and the like, is shown in FIG. 11B.

In the light emitting device in the example 8 or light emitting devices in examples 9 to 11 to be described later,

a seed crystal layer growth region 52 is provided to a surface of a part of the substrate (GaN substrate) 11 adjacent to the first light reflection layer 41 (hereinafter, referred to as “the surface region 51” in some cases),

a seed crystal layer 61 is formed on the seed crystal layer growth region 52,

the first compound semiconductor layer (specifically, the lower layer 21A of the first compound semiconductor layer) is formed from the seed crystal layer 61 on the basis of lateral direction epitaxial growth, and

the thickness of the seed crystal layer 61 is smaller than that of the first light reflection layer 41.

Note that when the thickness of the seed crystal layer 61 is represented by T_{seed} and the thickness of the first light reflection layer 41 is represented by T₁, the following relationship,

0.1≦T_{seed}/T₁<1,

is satisfied. Specifically, the following relationship,

T_{seed}/T₁=0.67,

is satisfied, but it is not limited thereto.

In the light emitting device in the example 8, a concavo-convex portion 53 is formed on a surface of a part of the substrate 11 adjacent to the first light reflection layer 41 (the surface region 51), and a convex portion 53A constitutes the seed crystal layer growth region 52. Specifically, this convex portion 53A corresponds to a part of the exposed surface of the substrate 11. Then, a cross-sectional shape obtained by cutting a part of the substrate 11 adjacent to the first light reflection layer 41 on a virtual vertical surface including a normal lien that passes through the central point of the first light reflection layer 41 (hereinafter, referred to simply as “the virtual vertical surface” in some cases) is a shape in which a concave portion 53B, the convex portion 53A, and the concave portion 53B are arranged in the stated order. Furthermore, the top surface of the convex portion 53A constitutes the seed crystal layer growth region 52. When the length of the convex portion 53A and the total length of the concave portion 53B in the virtual vertical surface are respectively represented by L_{cv} and L_{cc}, the following relationship,

0.2≦L_{cv}/(L_{cv}+L_{cc})≦0.9,

is satisfied. Specifically, the following relationship,

L_{cv}/(L_{cv}+L_{cc})=0.7,

is satisfied.

Further, in the light emitting device in the example 8 or the light emitting devices in the examples 9 to 11 to be described later, the cross-sectional shape of the seed crystal layer 61 (specifically, the cross-sectional shape of the seed crystal layer 61 in the virtual vertical surface) is an isosceles trapezoid [inclination angle of legs (inclined surface): 58 degrees]. Note that the crystal surface of the legs (inclined surface) of the isosceles trapezoid is a {11-22} surface. Furthermore, in the light emitting device in the example 8 or the light emitting devices in the examples 9 to 11 to be described later, when

the length of a region of the substrate located between the first light reflection layer 41 and the selective growth mask layer 44 adjacent thereto when the light emitting device is cut on a virtual vertical surface including normal lines that pass through central points of the first light reflection layer 41 and the selective growth mask layer 44 adjacent thereto is represented by L₀,

the dislocation density of a region of the first compound semiconductor layer 21 located on the upper side of this region of the substrate in this virtual vertical surface is represented by D₀, and

the dislocation density of a region of the first compound semiconductor layer 21 located on a region of the first light reflection layer 41 from the edge of the first light reflection layer 41 to the distance L₀ in this virtual vertical surface is represented by D₁,

the following relationship,

D₁/D₀≦0.2,

is satisfied.

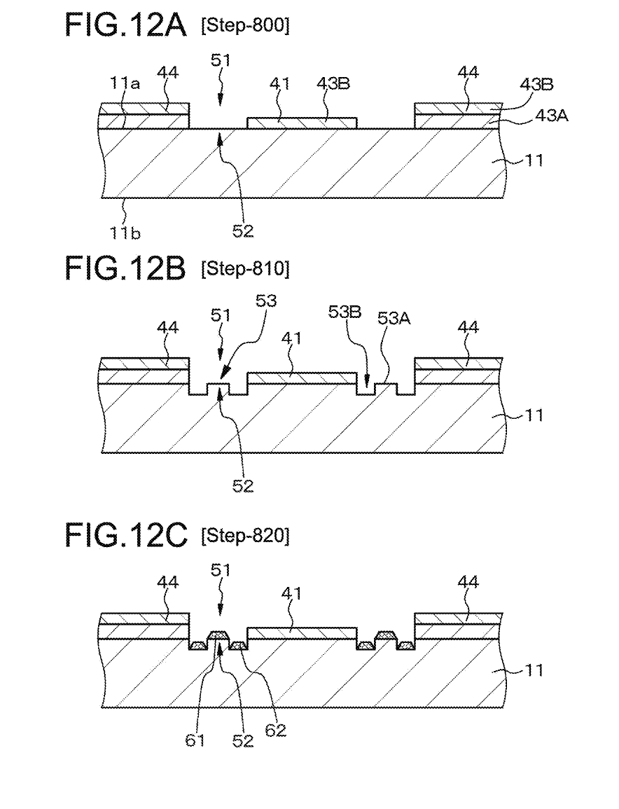

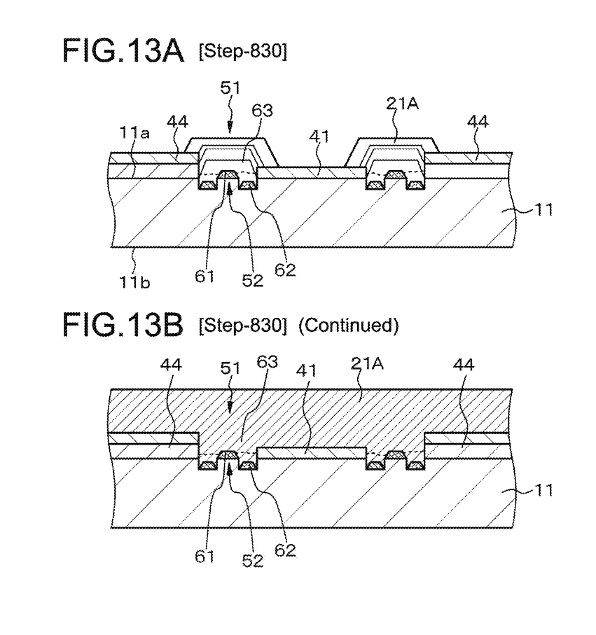

Hereinafter, a method of manufacturing the light emitting device in the example 8 will be described with reference to FIG. 12A, FIG. 12B, FIG. 12C, FIG. 13A, and FIG. 13B, which are each a schematic partial end view of a laminated structure 20 and the like.

[Step-800]

First, by performing a step similar to [step-100] in the example 1, the first light reflection layer 41 and the selective growth mask layer 44 are formed on the substrate (specifically, GaN substrate) 11 (see FIG. 12A).

[Step-810]

Next, the seed crystal layer growth region 52 is formed on a surface of a part of the substrate 11 adjacent to the first light reflection layer 41 (the surface region 51). Specifically, an etching mask is formed on the surface region 51 on the basis of a well-known method, and a part of the surface region 51 in which the convex portion 53A is to be formed is covered by the etching mask. A part of the surface region 51 in which the concave portion 53B is to be formed is exposed. Then, after the part of the substrate 11 in which the concave portion 53B is to be formed is etched on the basis of a well-known method, the etching mask is removed. Thus, the state shown in FIG. 12B can be obtained. Specifically, the concavo-convex portion 53 is formed in the surface region 51, and the convex portion 53A constitutes the seed crystal layer growth region 52.

[Step-820]

Next, the seed crystal layer 61 thinner than the first light reflection layer 41 is formed on the seed crystal layer growth region 52. Specifically, the seed crystal layer 61 is formed on the seed crystal layer growth region 52 by using an MOCVD apparatus on the basis of an MOCVD method using a TMG gas and a SiH₄ gas. The cross-sectional shape of the seed crystal layer 61 in the virtual vertical surface is an isosceles trapezoid [inclination angle of legs (inclined surface): 58 degrees] although it depends on the deposition conditions in the MOCVD method. Thus, the state shown in FIG. 12C can be obtained. Note that also on the bottom surface of the concave portion 53B, a seed crystal 62 whose cross-sectional shape is an isosceles trapezoid is generated. Further, in [step-810], after forming the concave portion 53B by etching a part of the substrate 11, the bottom surface of the concave portion 53B is further roughened to form a fine concavo-convex portion on the bottom surface of the concave portion 53B. Accordingly, a seed crystal is unlikely to be generated on the bottom surface of the concave portion 53B.

[Step-830]

Continuously, steps similar to [step-110] and subsequent steps in the example 1 such as changing the deposition conditions in the MOCVD method and forming the lower layer 21A of the first compound semiconductor layer from the seed crystal layer 61 on the basis of lateral direction epitaxial growth are performed. Thus, eventually, the structure shown in FIG. 11A can be obtained. Note that the state of the lower layer 21A of the first compound semiconductor layer that is being deposited is shown in FIG. 13A, and the state of the lower layer 21A of the first compound semiconductor layer after the deposition is finished is shown in FIG. 13B. In FIG. 13A, addition of a diagonal line to the lower layer 21A of the first compound semiconductor layer is omitted. Dotted lines represented by a reference number 63 indicate a dislocation that extends from the seed crystal layer 61 in the substantially horizontal direction. Because the thickness of the seed crystal layer 61 is smaller than that of the first light reflection layer 41, generally, the dislocation 63 extends to the side wall of the first light reflection layer 41, stops there, and does not extend to a part of the lower layer 21A of the first compound semiconductor layer formed on the first light reflection layer 41.

As described above, in the light emitting device in the example 8 and the method of manufacturing the same, a seed crystal layer growth region is provided, a seed crystal layer is formed on the seed crystal layer growth region, and the thickness of the seed crystal layer is smaller than that of the first light reflection layer. Therefore, when a compound semiconductor layer is caused to grow from the seed crystal layer on the basis of lateral direction epitaxially growth, the dislocation from the seed crystal layer does not extend to a deep part of the first compound semiconductor layer on the first light reflection layer, and the characteristics of the light emitting device are not adversely affected. Further, it is possible to reliably form a seed crystal layer in the seed crystal layer growth region located on a surface of a part of the substrate adjacent to the first light reflection layer. Furthermore, it is possible to reliably cover the first light reflection layer with a thin first compound semiconductor layer because the size of the seed crystal layer can be reduced even in the case where the area of the first light reflection layer is large.

### Example 9

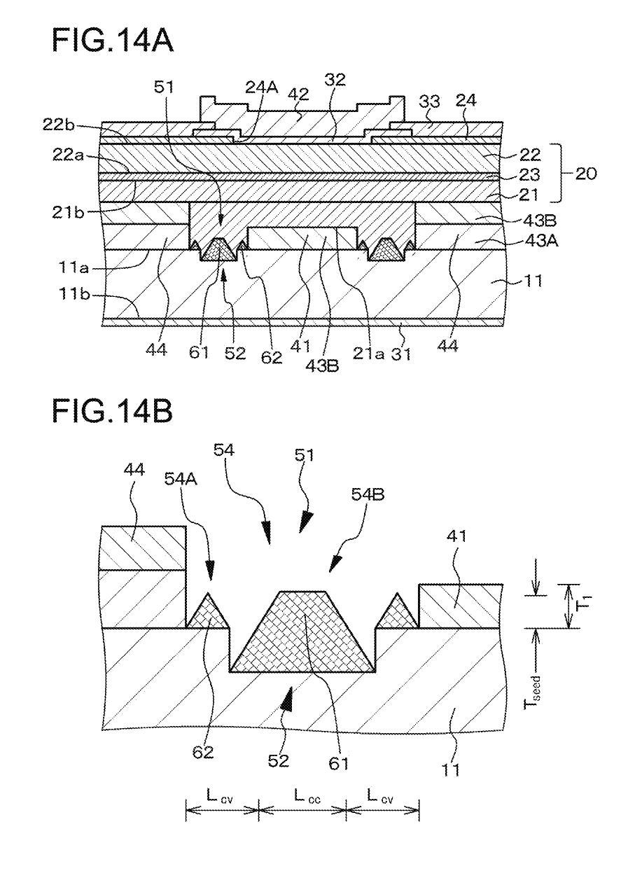

The example 9 is modification of the example 8, and relates to the light emitting device having the 7-B-th configuration. As shown in a schematic partial cross-sectional view of FIG. 14A and a schematic partial end view obtained by enlarging a surface region of a substrate and the like in FIG. 14B, in a light emitting device in the example 9, a concavo-convex portion 54 is formed on a surface of a part of the substrate (GaN substrate) 11 adjacent to the first light reflection layer 41 (the surface region 51), and a concave portion 54B constitutes the seed crystal layer growth region 52. Specifically, this concave portion 54B corresponds to a part of the exposed surface of the substrate 11. Then, the cross-sectional shape obtained by cutting a part of the substrate 11 adjacent to the first light reflection layer 41 on the virtual vertical surface is the shape in which a convex portion 54A, the concave portion 54B, and the convex portion 54A are arranged in the stated order. Furthermore, the bottom surface of the concave portion 54B constitutes the seed crystal layer growth region 52. When the length of the concave portion 54B and the total length of the convex portion 54A in the virtual vertical surface are respectively represented by L_{cc} and L_{cv}, the following relationship,

0.2≦L_{cc}/(L_{cv}+L_{cc})≦0.9,

is satisfied. Specifically, the following relationship,

L_{cc}/(L_{cv}+L_{cc})=0.7,

is satisfied.

Other than the above, the configuration and structure of the light emitting device in the example 9 can be similar to those of the light emitting device in the example 8. Also the method of manufacturing the light emitting device in the example 9 can be substantially similar to the method of manufacturing the light emitting device in the example 8. Therefore, detailed description is omitted.

Note that after forming the selective growth mask layer 44 and exposing the substrate 11 in a step similar to [step-800] in the example 8, a fine concavo-convex portion is formed on the exposed surface of the substrate 11. After that, by forming the concave portion 54B in a step similar to [step-810] in the example 8, a seed crystal is unlikely to be generated on the top surface of the convex portion 54A on which the concavo-convex portion is formed.

### Example 10

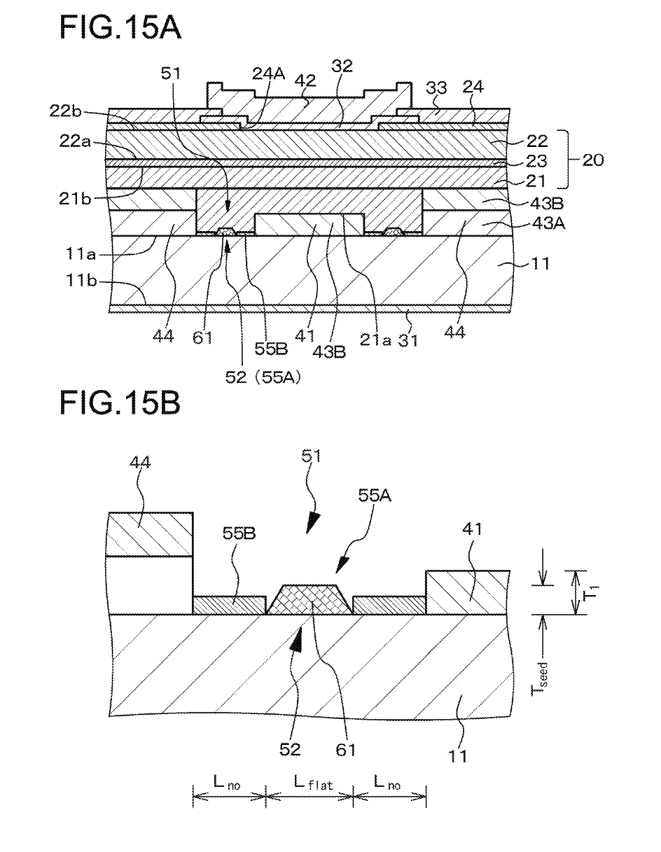

Also an example 10 is modification of the example 8, but relates to the light emitting device having the 7-C-th configuration. As shown in a schematic partial cross-sectional view of FIG. 15A and a schematic partial end view obtained by enlarging a surface of a substrate and the like in FIG. 15B, in the light emitting device in the example 10, a part of the substrate (GaN substrate) 11 adjacent to the first light reflection layer 41 has a structure in which a non-crystal growth portion 55B, a flat portion 55A, and the non-crystal growth portion 55B are arranged in the stated order, and the flat portion 55A constitutes the seed crystal layer growth region 52. Specifically, this flat portion 55A corresponds to a part of the exposed surface of the substrate. Then, when the length of the flat portion 55A and the total length of the non-crystal growth portion 55B in the virtual vertical surface are respectively represented by L_{flat} and Lₙₒᵥ, the following relationship,

0.2≦L_{flat}/(L_{flat}+Lₙₒ)≦0.9,

is satisfied. Specifically, the following relationship,

L_{flat}/(L_{flat}+Lₙₒ)=0.7,

is satisfied. Further, the non-crystal growth portion 55B is formed of silicon nitride (SiN_{X}). Note that in the case where the non-crystal growth portion 55B is formed also on the uppermost layer of the first light reflection layer 41 (layer adjacent to the lower layer 21A of the first compound semiconductor layer), when the thickness of the non-crystal growth portion 55B (the uppermost layer of the first light reflection layer 41) is represented by t₂ and the refractive index of the non-crystal growth portion 55B is represented by n_{2f} the following relationship,

t₂=λ₀/(4n₂),

is favorably satisfied. Furthermore, when the following relationship,

t₂=λ₀/(2n₂),

is satisfied, the uppermost layer of the first light reflection layer 41 is an absence layer for light having the wavelength λ₀.

Specifically, in the example 10, in a step similar to [step-810] in the example 8, a lift-off mask is formed on the surface region 51 on the basis of a well-known method, and a part of the surface region 51 of the substrate 11 in which the flat portion 55A is to be formed is covered with the lift-off mask. A part of the substrate 11 in which the non-crystal growth portion 55B is to be formed is exposed. Then, after forming the non-crystal growth portion 55B on an entire surface on the basis of a well-known method, the lift-off mask and a part of the non-crystal growth portion 55B formed thereon are removed.

Other than the above, the configuration and structure of the light emitting device in the example 10 can be similar to those of the light emitting device in the example 8, and also the method of manufacturing the light emitting device in the example 10 can be substantially similar to the method of manufacturing the light emitting device in the example 8. Therefore, detailed description thereof will be omitted.

Note that by forming the lowermost layer or lower layer of the first light reflection layer on the substrate 11 in a step similar to [step-800] in the example 8 and performing patterning, the non-crystal growth portion 55B and the flat portion 55A that extend from the lowermost layer or lower layer of the first light reflection layer may be formed. Then, after that, it only needs to form the remaining part of the first light reflection layer on the lowermost layer or lower layer of the first light reflection layer. Alternatively, in the above-mentioned example 7, by forming the thermal expansion relaxation film 46 constituting the lowermost layer of the first light reflection layer on the substrate 11 and performing patterning, the non-crystal growth portion 55B and the flat portion 55A including the extended portion of the thermal expansion relaxation film 46 may be formed. Then, after that, it only needs to form the remaining part of the first light reflection layer on the thermal expansion relaxation film 46.

### Example 11

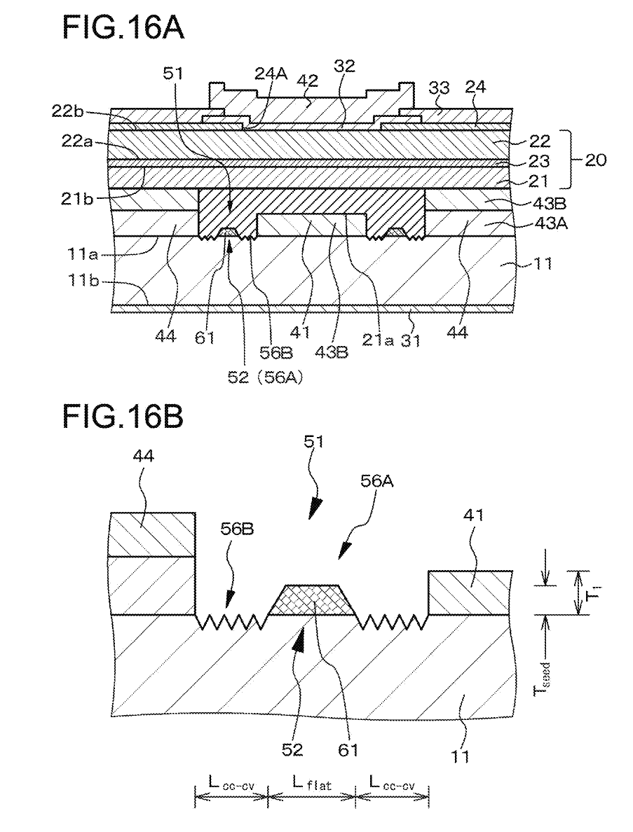

Also an example 11 is modification of the example 8, but relates to the light emitting device having the 7-D-th configuration. As shown in a schematic partial cross-sectional view of FIG. 16A and a schematic partial end view obtained by enlarging a surface region of a substrate and the like in FIG. 16B, in the light emitting device in the example 11, a part of the substrate (GaN substrate) 11 adjacent to the first light reflection layer 41 has a structure in which a concavo-convex portion 56B, a flat portion 56A, and the concavo-convex portion 56B are arranged in the stated order, and the flat portion 56A constitutes the seed crystal layer growth region 52.

Specifically, this flat portion 56A corresponds to a part of the exposed surface of the substrate 11. In the concavo-convex portion 56B, a seed crystal is unlikely to be generated. Then, when the length of the flat portion 56A and the total length of the concavo-convex portion 56B in the virtual vertical surface are respectively represented by L_{flat} and L_{cc-cv}, the following relationship,

0.2≦L_{flat}/(L_{flat}+L_{cc-cv})≦0.9,

is satisfied. Specifically, the following relationship,

L_{flat}/(L_{flat}+L_{cc-cv})=0.7,

is satisfied.

Specifically, in the example 11, an etching mask is formed on the surface region 51 of the substrate 11 on the basis of a well-known method in a step similar to [step-810] in the example 8 and the flat portion 56A in the surface region 51 of the substrate 11 is covered with the etching mask. A part of the substrate 11 in which the concavo-convex portion 56B is to be formed is exposed. Then, after etching the part of the substrate 11 in which the concavo-convex portion 56B is to be formed, the etching mask is removed, on a basis of a well-known method.

Other than the above, the configuration and structure of the light emitting device in the example 11 can be similar to those of the light emitting device in the example 8, and also the method of manufacturing the light emitting device in the example 11 can be substantially similar to the method of manufacturing the light emitting device in the example 8. Therefore, detailed description thereof will be omitted.

### Example 12

An example 12 is modification of the example 6.

Meanwhile, in the case where the thickness of the first compound semiconductor layer 21 is large, when light returns between the first light reflection layer 41 and the second light reflection layer 42, the light is dissipated outside the resonator and is lost. Accordingly, a problem such as an increase in the threshold value of the surface emitting laser device, deterioration of differential efficiency, and then an increase in operation voltage and reduction in reliability may occur.

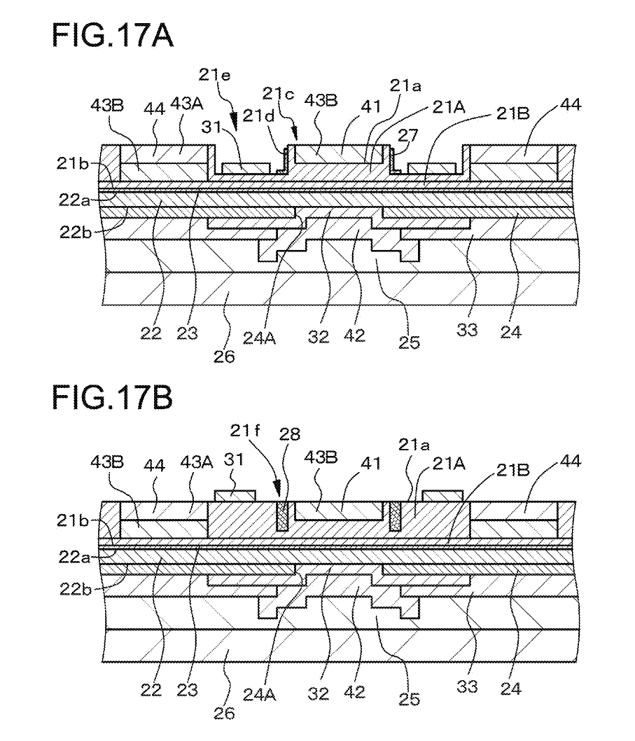

As shown in a schematic partial end view of FIG. 17A, in the surface emitting laser device in the example 12, a projection portion 21c is formed in the first surface 21a of the first compound semiconductor layer 21, the first light reflection layer 41 is formed on this projection portion 21c, and the first electrode 31 is formed in a concave portion 21e on the periphery of the projection portion 21c formed on the first surface 21a of the first compound semiconductor layer 21. Specifically, in the example 12, the first compound semiconductor layer 21 has a so-called mesa-shape. The plane shape of the projection portion 21c is a regular hexagon. As described above, by making the first compound semiconductor layer 21 having a mesa-shape, it is possible to reliably prevent light from being dissipated outside the resonator when the light returns between the first light reflection layer 41 and the second light reflection layer 42, and there is no fear that a problem such as an increase in operation voltage and reduction in reliability occurs.

The plane shape of the first electrode 31 is annular. The plane shape of the device region is circular, and also plane shapes of the first light reflection layer 41, the second light reflection layer 42, and the opening 24A provided to the current constriction layer 24 are circular.

The height of the projection portion 21c is less than the thickness of the first compound semiconductor layer 21, and examples of the height of the projection portion 21c include not less than 1×10⁻⁸ m and not more than 1×10⁻⁵ m, and specifically, 2×10⁻⁶ m. The size of the projection portion 21c is larger than those of the first light reflection layer 41 and the device region.

On a side surface (side wall) 21d of the projection portion 21c, a dielectric layer 27 formed of SiO₂, SiN, AlN, ZrO₂, Ta₂O₅, or the like, is formed. Accordingly, it is possible to more reliably prevent light from being dissipated outside the resonator when the light returns between the first light reflection layer 41 and the second light reflection layer 42. Note that the value of the refractive index of the material forming the dielectric layer 27 is favorably smaller than that of the value of the average refractive index of the material forming the first compound semiconductor layer 21.

Other than the above, the configuration and structure of the surface emitting laser device in the example 12 can be similar to those of the surface emitting laser device in the example 6. Therefore, detailed description thereof will be omitted.

In order to obtain the surface emitting laser device in the example 12, it only needs to form the projection portion 21c and the concave portion 21e on the first surface 21a of the first compound semiconductor layer 21, and the dielectric layer 27 on the side surface (side wall) 21d of the projection portion 21c, between [step-620] and [step-630] of the surface emitting laser device in the example 6.

### Example 13

Also an example 13 is modification of the example 6. As shown in a schematic partial cross-sectional view of FIG. 17B, in a light emitting device in the example 13, an annular groove portion 21f is formed so as to surround the first light reflection layer 41 formed on the first surface 21a of the first compound semiconductor layer 21, and the groove portion 21f is filled with an insulating material. Specifically, in the groove portion 21f, an insulating material layer 28 formed of SiO₂, SiN, AlN, ZrO₂, Ta₂O₅, or the like, is formed. As described above, by making the first compound semiconductor layer 21 having a kind of mesa-shape, i.e., by filling the annular groove portion 21f with an insulating material, it is possible to prevent light from being dissipated outside the resonator when the light returns between the first light reflection layer 41 and the second light reflection layer 42, and there is no fear that a problem such as an increase in operation voltage and reduction in reliability occurs.

The depth of the groove portion 21f is less than the thickness of the first compound semiconductor layer 21, and examples of the depth of the groove portion 21f include not less than 1×10⁻⁸ m and not more than 1×10⁻⁵ m, and specifically, 2×10⁻⁶ m. The inner diameter of the groove portion 21f is larger than those of the first light reflection layer 41 and the device region.

Other than the above, the configuration and structure of the surface emitting laser device in the example 13 can be similar to those of the surface emitting laser device in the example 6. Therefore, detailed description thereof will be omitted.

In order to achieve the surface emitting laser device in the example 13, instead of forming the projection portion 21c and the concave portion 21e on the first surface 21a of the first compound semiconductor layer 21 in a step of manufacturing the surface emitting laser device in the example 12, it only needs to form the groove portion 21f, and the insulating material layer 28 in the groove portion 21f.

### Example 14

An example 14 is modification of the examples 1 to 13.

Meanwhile, in a nitride compound light emitting device that emits blue or green light, the mount of current injection is increased as the light emission wavelength is increased. As a result, there is fear that the light emission efficiency is reduced and the threshold value current is increased. Examples of the cause thereof include non-uniformity of carriers in the active layer (light emitting layer). Specifically, as the light emission wavelength is increased, the energy gap difference between a barrier layer and a well layer constituting a multiquantum well structure is increased. Further, when the active layer is formed on the c surface of the GaN substrate, the well layer and the barrier layer are affected by the piezo electric field. A carrier (electron or hole) that has entered a well layer once is hard to go outside the well layer. Due to these, the non-uniformity of carriers in the active layer (light emitting layer) occurs.

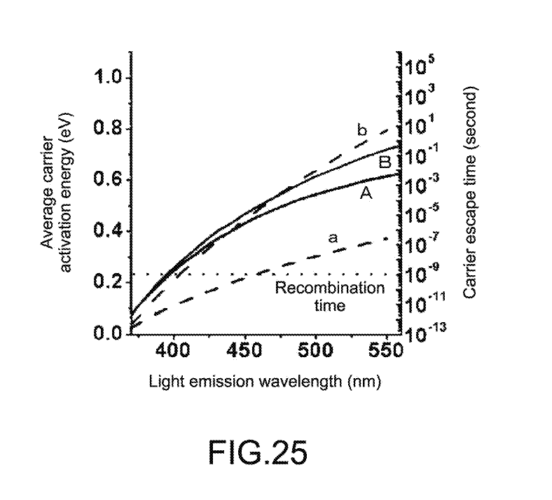

An example in which these phenomena are represented by numerical calculation is shown in Non-Patent Document 1, IEEE, Journal of Selected Topics in Quantum Electronics Vol. 15 No. 5 (2011) p. 1390. In accordance with this Non-Patent Document 1, the state where the carrier in the well layer is hard to go outside the well layer when the light emission wavelength is not less than 400 nm in the case where the active layer is formed on the c surface of the GaN substrate, or when the light emission wavelength is not less than 450 nm in the case where the active layer is formed on a non-polarity surface of the GaN substrate, is shown by the relationship between the light emission recombination time and carrier escape time from the well layer (see FIG. 25). Note that in FIG. 25, “A” represents behavior of a hole of the case where the active layer is formed on the c surface of the GaN substrate, “B” represents behavior of an electron of the case where the active layer is formed on the c surface of the GaN substrate, “a” represents behavior of a hole of the case where the active layer is formed on the non-polarity surface of the GaN substrate, and “b” represents behavior of an electron of the case where the active layer is formed on the non-polarity surface of the GaN substrate. Normally, carrier movement between well layers in a multiquantum well structure including two or more well layers is performed in a very short time not more than approximately 100 femtoseconds. However, because of the above-mentioned reason, the carrier escape time from a well layer is increased, and an electron or hole cannot freely go and come between the well layers. As a result, the electron concentration and hole concentration are different for each well layer. Because the remaining carrier does not contribute to light emission, the light emission efficiency is reduced. Further, the carrier concentration is significantly changed between the well layers. This leads to discrepancy of the light emission wavelength or discrepancy of the gain peak (wavelength). Also this is a factor of reduction in the light emission efficiency or the increase in threshold value current.

A technology in which a tunnel barrier layer is formed to reduce such differences of electron concentration and hole concentration between the well layers is disclosed in, for example, Japanese Patent Application Laid-open No. 2000-174328. Specifically, in the technology disclosed in this published unexamined patent application, the thickness of the tunnel barrier layer is controlled to change the tunnel probability in the tunnel barrier layer. However, in the case where a difference between effective masses of an electron and a hole is large, the non-uniformity of the carriers is not fully eliminated even if such a tunnel barrier layer is provided. Although it is conceivable that only the thickness of the barrier layer can be reduced without forming the tunnel barrier layer, such a problem that the light emission efficiency of an adjacent well layer is reduced occurs when the thickness of the barrier layer is reduced. For example, it has been known that in the light emitting device having a light emission wavelength of 520 nm, the light emission efficiency of the case where the thickness of the barrier layer is 2.5 nm is approximately ¼ of that of the case where the thickness of the barrier layer is 10 nm.

In the example 14 or examples 15 and 16 to be described later, the active layer 23 has a multiquantum well structure including a tunnel barrier layer. Then, in the example 14, the composition fluctuation of a well layer adjacent to the second compound semiconductor layer is larger than that of a different well layer.

In the example 14 or examples 15 and 16 to be described later, the tunnel barrier layer may be formed between a well layer and a barrier layer. As an example, in the case where the active layer includes two well layers and one barrier layer, a structure including a first well layer, a first tunnel barrier layer, a barrier layer, a second tunnel barrier layer, and a second well layer from the side of the first compound semiconductor layer is obtained. Note that the number of well layers constituting the active layer is not limited thereto, and it goes without saying that the number of well layers may be not less than 3. Further, the thickness of the tunnel barrier is favorably not more than 4 nm. The lower limit value of the thickness of the tunnel barrier layer is not particularly limited as long as the tunnel barrier can be formed. The thickness of the tunnel barrier may be constant or different.

The composition fluctuation or composition of the well layer can be measured on the basis of three-dimensional atom probe (3DAP), for example. In the case where the active layer is formed of AlInGaN-based compound semiconductor, it only needs to measure the composition fluctuation or composition of In on the basis of the three-dimensional atom probe. Regarding the three-dimensional atom probe, see http://www.nanoanalysis.co.jp/business/case_example_49.html, for example. Note that in the three-dimensional atom probe, the number of In composition and the composition thereof can be counted. In the case where when the In composition and the count number of the In composition are respectively represented in a horizontal axis and a vertical axis by using a histogram or the like, a full width at half maximum, variance, a standard deviation, and the like of a histogram of a well layer adjacent to the second compound semiconductor layer are larger than those of a histogram of a different well layer, it can be said that the composition fluctuation of the well layer adjacent to the second compound semiconductor layer is larger than that of the different well layer. The value of the band gap energy in the light emitting device can be checked by an average value of the In composition measured by the above-mentioned three-dimensional atom probe, for example, and the thickness of the well layer can be obtained by an electron microscope with high resolution or the like. Examples of the value obtained by subtracting the maximum value in the band gap energy of a different well layer from the band gap energy of the well layer adjacent to the second compound semiconductor layer include, but not limited to, 1×10⁻⁴ eV to 2×10⁻¹ eV. Further, examples of the value obtained by subtracting the maximum value in the thickness of a different well layer from the thickness of the well layer adjacent to the second compound semiconductor layer include, but not limited to, 0.05 nm to 2 nm.

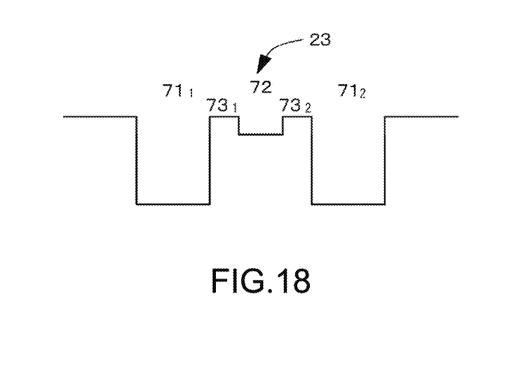

In the light emitting device in the example 14, a structure schematic view of the multiquantum well structure in the active layer 23 is shown in FIG. 18. In the example 14 or examples 15 and 16 to be described later, the active layer 23 includes two well layers 71₁ and 71₂ and one barrier layer 72. More specifically, the active layer 23 has a multiquantum well structure including a first well layer 71₁, a first tunnel barrier layer 73₁, the barrier layer 72, a second tunnel barrier layer 73₂, and a second well layer 71₂ from the side of the first compound semiconductor layer 21. The thickness of each of the tunnel barrier layers 73₁ and 73₂ is not more than 4 nm.

Here, the configuration of the active layer 23 in the light emitting device in the example 14 is as shown in Table 4. Note that it only needs to make the value of the In composition in the two tunnel barrier layers 73₁ and 73₂ smaller than that in the barrier layer 72.

TABLE 4
Active layer

Second well layer In_{0.30}Ga_{0.70}N (thickness: 2.5 nm)
Second tunnel barrier layer GaN (thickness: 2.0 nm)
Barrier layer In_{0.05}Ga_{0.95}N (thickness: 4.0 nm)
First tunnel barrier layer GaN (thickness: 2.0 nm)
First well layer In_{0.30}Ga_{0.70}N (thickness: 2.5 nm)

Here, in the light emitting device in the example 14, the composition fluctuation of the well layer adjacent to the second compound semiconductor layer is larger than that of a different well layer. Specifically, when the laminated structure 20 is deposited on the basis of an MOCVD, the In composition fluctuation in the well layers 71₁ and 71₂ is increased by making the growth rate, deposition temperature, and/or deposition pressure of the first well layer 711 different from those of the second well layer 712. The In composition fluctuation or composition can be measured on the basis of a three-dimensional atom probe (3DAP) as described above. Specifically, by the measurement using the three-dimensional atom probe, when the In composition and the count number of In composition are respectively represented in a horizontal axis and a vertical axis by using a histogram or the like, such a result in which a full width at half maximum of a histogram of the well layer adjacent to the second compound semiconductor layer is larger than that of a histogram of a different well layer has been obtained.

In the light emitting device in the example 14 or light emitting devices in examples 15 and 16 to be described later, distribution of electrons is biased to the side of the second compound semiconductor layer by introducing the tunnel barrier layer. As a result, the light emission peak wavelength or optical gain peak wavelength of the well layer adjacent to the second compound semiconductor layer is different from those of a different well layer. Specifically, in the well layer adjacent to the second compound semiconductor layer, these wavelengths are decreased. Because the composition fluctuation of the well layer adjacent to the second compound semiconductor layer is made larger than that of a different well layer in the light emitting device in the example 14, the band gap energy of the well layer adjacent to the second compound semiconductor layer is made smaller than that of a different well layer in the light emitting device in the example 15 to be described later, and the thickness of the well layer adjacent to the second compound semiconductor layer is made larger than that of a different well layer in the light emitting device in the example 16 to be described later, it is possible to make the light emission peak wavelength or optical gain peak wavelength constant between well layers, or suppress peeling. Then, as a result of the above, it is possible to improve the light emission efficiency and reduce the threshold value current.

### Example 15

An example 15 is modification of the example 14. In the example 15, the band gap energy of a well layer adjacent to the second compound semiconductor layer (specifically, the second well layer 71₂) is smaller than that of a different well layer (specifically, the first well layer 71₁) (see Table 6). The configuration of the active layer 23 in the light emitting device in the example 15 is as shown in Table 5. By making the supply amount of trimethylindium (TMI) gas as an In source at the time of deposition of the second well layer 71₂ larger than the supply amount of trimethylindium gas as an In source at the time of deposition of the first well layer 71₁ or increasing the growth rate when the laminated structure 20 is deposited on the basis of an MOCVD method, the band gap energy of a well layer adjacent to the second compound semiconductor layer (the second well layer 71₂) can be smaller than the band gap energy of a different well layer (specifically, the first well layer 71₁).

TABLE 5
Active layer

Second well layer In_{0.19}Ga_{0.81}N (thickness: 2.5 nm)
Second tunnel barrier layer GaN (thickness: 2.0 nm)
Barrier layer In_{0.04}Ga_{0.96}N (thickness: 4.0 nm)
First tunnel barrier layer GaN (thickness: 2.0 nm)
First well layer In_{0.18}Ga_{0.82}N (thickness: 2.5 nm)

TABLE 6

| | |
|---|---|
| Band gap energy of second well layer | 71₂ 2.695eV |
| Band gap energy of first well layer | 71₁ 2.654eV |

### Example 16

Also an example 16 is modification of the example 14. In the example 16, the thickness of a well layer adjacent to the second compound semiconductor layer (specifically, the second well layer 71₂) is larger than that of a different well layer (specifically, the first well layer 71₁). The configuration of the active layer 23 in the light emitting device in the example 16 is as shown in Table 7. By making the deposition time of the second well layer 71₂ longer than the deposition time of the first well layer 71₁ or increasing the growth rate when the laminated structure 20 is deposited on the basis of an MOCVD method, the thickness of a well layer adjacent to the second compound semiconductor layer (the second well layer 71₂) can be larger than that of a different well layer (specifically, the first well layer 71₁).

TABLE 7
Active layer

Second well layer In_{0.18}Ga_{0.82}N (thickness: 2.8 nm)
Second tunnel barrier layer GaN (thickness: 2.0 nm)
Barrier layer In_{0.05}Ga_{0.95}N (thickness: 4.0 nm)
First tunnel barrier layer GaN (thickness: 2.0 nm)
First well layer In_{0.18}Ga_{0.82}N (thickness: 2.5 nm)

Note that the example 14 and the example 15 can be combined with each other, the example 14 and the example 16 can be combined with each other, the example 15 and the example 16 can be combined with each other, and the example 14, the example 15, and the example 16 can be combined with each other,

Although the present disclosure has been described on the basis of favorable examples in the above, the present disclosure is not limited to these examples. The configuration and structure of the light emitting device described in the examples are merely examples, and can be appropriately changed. Also the method of manufacturing the light emitting device in the examples can be appropriately changed.

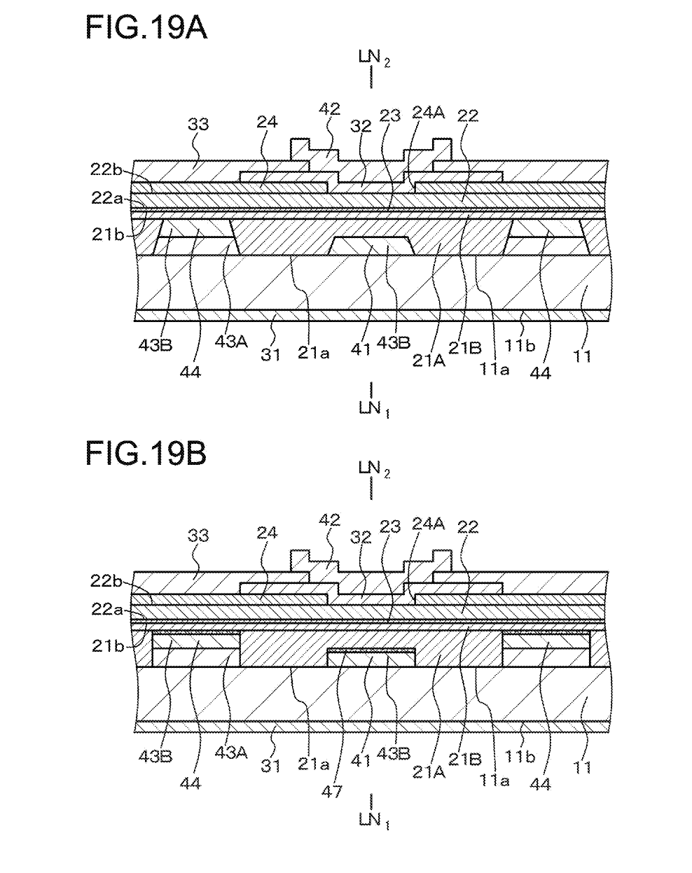

The cross-sectional shape of the first light reflection layer is rectangular in each example. However, it is not limited thereto, and can be a trapezoidal shape as shown in FIG. 19A. Further, as shown in FIG. 19B, the uppermost layer (adjacent to the first compound semiconductor layer 21) 47 of the first light reflection layer 41 may be formed of a silicon nitride film. Then, in this case, when the thickness of the uppermost layer 47 of the first light reflection layer 41 is represented by t₂ and the refractive index of the uppermost layer 47 of the first light reflection layer 41 is represented by n₂, the following relationship,

t₂=λ₀/(2n₂),

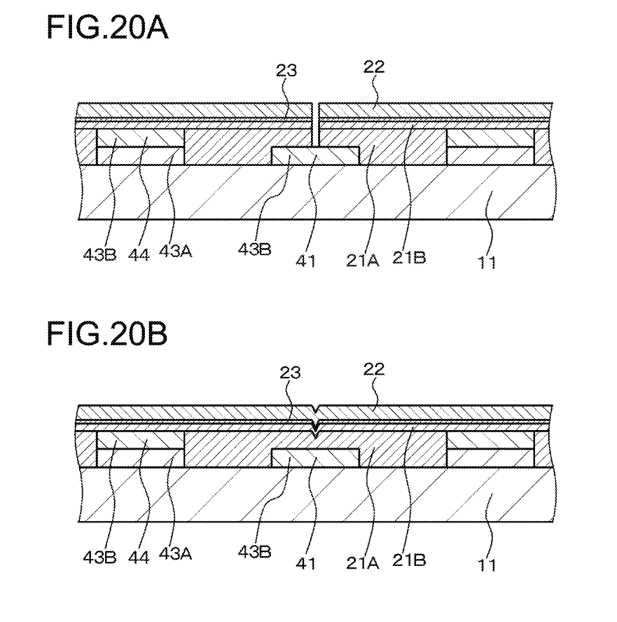

is favorably satisfied. Accordingly, the uppermost layer 47 of the first light reflection layer 41 is transparent for light having the wavelength λ₀. Furthermore, in the example shown in FIG. 11A, the first light reflection layer 41 is fully covered with the first compound semiconductor layer 21. A part of the first light reflection layer 41 may be exposed (see FIG. 20A), and the first compound semiconductor layer 21 on the first light reflection layer 41 does not necessary need to be fully flat (see FIG. 20B). Note that in FIG. 20A and FIG. 20B, illustration of the current constriction layer 24, the second electrode 32, the pad electrode 33, the second light reflection layer 42, and the first electrode 31 is omitted. It only needs to manufacture the light emitting device in a region other than a region in which the first light reflection layer 41 is exposed and a region in which the first compound semiconductor layer 21 is not fully flat.

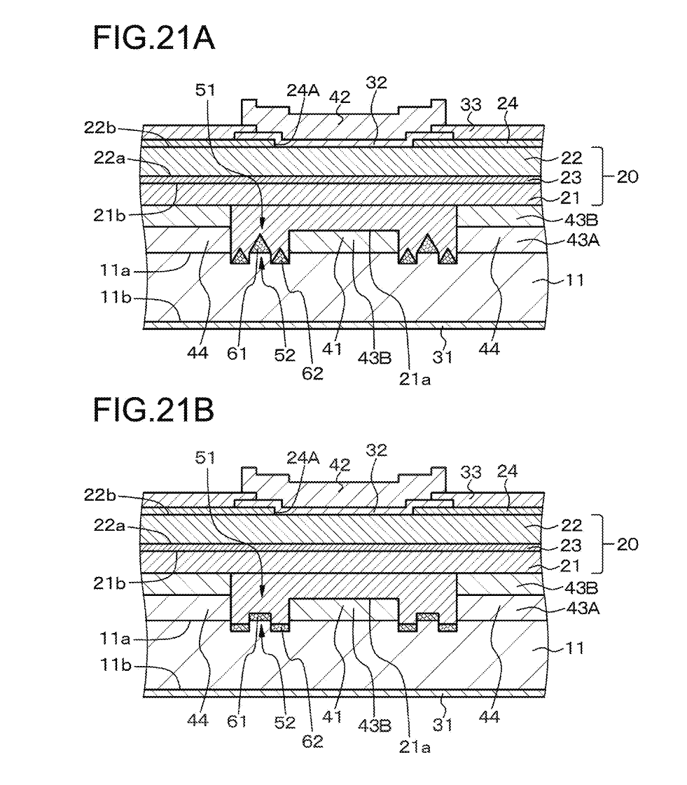

The cross-sectional shape of the seed crystal layer 61 in the virtual vertical surface is not limited to an isosceles trapezoid, and can be an isosceles triangle as shown in a schematic partial end view of FIG. 21A and FIG. 21B or rectangular shape. In the case where the cross-sectional shape of the seed crystal layer 61 is an isosceles triangle, it only needs to cause the crystal growth of the seed crystal layer 61 to further proceed than the case where the cross-sectional shape is an isosceles trapezoid. In the case where the cross-sectional shape of the seed crystal layer 61 is a rectangular shape, it only needs to make the forming condition of the seed crystal layer 61 different from the forming condition for forming the cross-sectional shape of the seed crystal layer 61 in an isosceles trapezoid.

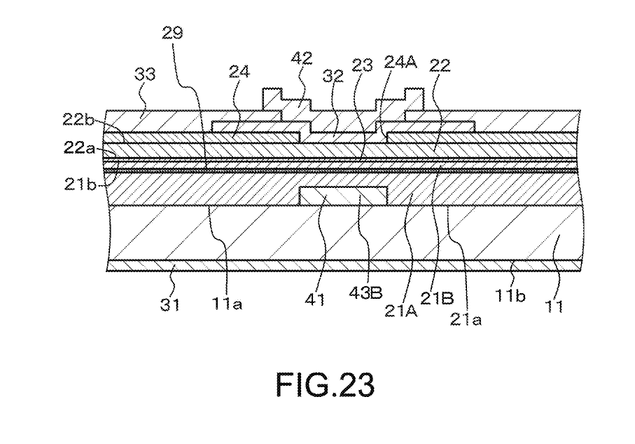

In the light emitting device according to the second aspect of the present disclosure, it does not necessarily need to provide a selective growth mask layer. As shown in a schematic partial cross-sectional view of FIG. 23, an impurity-containing compound semiconductor layer may be formed in a light emitting device to which no selective growth mask layer is provided. In the light emitting device shown in FIG. 23, the impurity-containing compound semiconductor layer 29 is formed in the first compound semiconductor layer (specifically, between the lower layer 21A and the upper layer 21B of the first compound semiconductor layer 21). Such an impurity-containing compound semiconductor layer 29 can be formed by forming the lower layer 21A of the first compound semiconductor layer 21 on the basis of an MOCVD method before performing ion-implantation or impurity diffusion processing on the top surface of the lower layer 21A of the first compound semiconductor layer 21, for example. Then, after that, it only needs to, for example, form the upper layer 21B of the first compound semiconductor layer 21, the active layer 23, and the second compound semiconductor layer 22.

It should be noted that the present technology may take the following configurations.

[A01] (Light emitting device: first aspect of the present disclosure)

A light emitting device, including:

a selective growth mask layer;

a first light reflection layer thinner than the selective growth mask layer;

a laminated structure including a first compound semiconductor layer, an active layer, and a second compound semiconductor layer, the first compound semiconductor layer being formed on the first light reflection layer; and

a second electrode formed on the second compound semiconductor layer, and a second light reflection layer, in which

the second light reflection layer is opposed to the first light reflection layer.

[A02] The light emitting device according to [A01], in which

a difference between a thickness of the selective growth mask layer and a thickness of the first light reflection layer is not less than 5×10⁻⁸ m.

[A03] The light emitting device according to [A01] or [A02], in which

the first light reflection layer is formed of a dielectric multilayer film, and

the selective growth mask layer includes, from a side of the active layer, a dielectric multilayer film having the same configuration as that of the dielectric multilayer film constituting the first light reflection layer, and a base layer.

[A04] The light emitting device according to [A01] or [A02], in which

the first light reflection layer is formed of a dielectric multilayer film, and

the selective growth mask layer includes, from a side of the active layer, a polishing stopper layer and a dielectric multilayer film having the same configuration as that of the dielectric multilayer film constituting the first light reflection layer.

[A05] The light emitting device according to [A01] or [A02], in which

the selective growth mask layer and the first light reflection layer are formed on a substrate,

the substrate has a concave portion and a convex portion,

the selective growth mask layer is formed in the convex portion of the substrate, and

the first light reflection layer is formed in the concave portion of the substrate.

[A06] The light emitting device according to [A05], in which

the selective growth mask layer is formed of a dielectric multilayer film having the same configuration as that of the dielectric multilayer film constituting the first light reflection layer.

[A07] The light emitting device according to [A01] or [A02], in which

the selective growth mask layer is formed of a dielectric multilayer film with a thickness different from that of the dielectric multilayer film constituting the first light reflection layer.

[A08] The light emitting device according to any one of [A01] to [A07], in which

the laminated structure includes an impurity-containing compound semiconductor layer.

[A09] The light emitting device according to [A08], in which

an impurity concentration of the impurity-containing compound semiconductor layer is not less than 10 times an impurity concentration of a compound semiconductor layer adjacent to the impurity-containing compound semiconductor layer.

[A10] The light emitting device according to [A08] or [A09], in which

an impurity concentration of the impurity-containing compound semiconductor layer is not less than 1×10¹⁷/cm³.

[A11] The light emitting device according to any one of [A08] to [A10], in which

an impurity contained in the impurity-containing compound semiconductor layer includes at least one kind of element selected from the group consisting of boron (B), potassium (K), calcium (Ca), sodium (Na), silicon (Si), aluminum (Al), oxygen (O), carbon (C), sulfur (S), halogen (chlorine (Cl) or fluorine (F)), and heavy metal (chromium (Cr), etc.).

[B01] (Light emitting device: second aspect of the present disclosure)

A light emitting device, including:

a first light reflection layer;

a laminated structure including a first compound semiconductor layer, an active layer, and a second compound semiconductor layer, the first compound semiconductor layer being formed on the first light reflection layer;

a second electrode formed on the second compound semiconductor layer, and a second light reflection layer; and

a first electrode, in which

the second light reflection layer is opposed to the first light reflection layer, and

an impurity-containing compound semiconductor layer is formed in the laminated structure.

[B02] The light emitting device according to [B01], in which

an impurity concentration of the impurity-containing compound semiconductor layer is not less than 10 times an impurity concentration of a compound semiconductor layer adjacent to the impurity-containing compound semiconductor layer.

[B03] The light emitting device according to [B01] or [B02], in which

an impurity concentration of the impurity-containing compound semiconductor layer is not less than 1×10¹⁷/cm³.

[B04] The light emitting device according to any one of [B01] to [B03], in which

an impurity contained in the impurity-containing compound semiconductor layer includes at least one kind of element selected from the group consisting of boron, potassium, calcium, sodium, silicon, aluminum, oxygen, carbon, sulfur, chlorine, fluorine, and chromium.

[C01] The light emitting device according to any one of [A01] to [B04], in which

a seed crystal layer growth region is provided on a surface of a part of the substrate adjacent to the first light reflection layer,

a seed crystal layer is formed on the seed crystal layer growth region,

the first compound semiconductor layer is formed from the seed crystal layer on the basis of lateral direction epitaxial growth, and

the thickness of the seed crystal layer is smaller than that of the first light reflection layer.

[C02] The light emitting device according to [C01], in which

when the thickness of the seed crystal layer is represented by T_{seed} and the thickness of the first light reflection layer is represented by T₁, the following relationship,

0.1≦T_{seed}/T1<1,

is satisfied.

[C03] The light emitting device according to [C01] or [C02], in which

a concavo-convex portion is formed on a surface of a part of the substrate adjacent to the first light reflection layer, and

a convex portion constitutes the seed crystal layer growth region.

[C04] The light emitting device according to [C03], in which

the cross-sectional shape obtained by cutting a part of the substrate adjacent to the first light reflection layer on the virtual vertical surface including a normal line that passes through the central point of the first light reflection layer is a shape in which a concave portion, the convex portion, and the concave portion are arranged in the stated order, and

the top surface of the convex portion constitutes the seed crystal layer growth region.

[C05] The light emitting device according to [C04], in which

when the length of the convex portion and the total length of the concave portion in the virtual vertical surface are respectively represented by L_{cv} and L_{cc}, the following relationship,

0.2≦L_{cv}/(L_{cv}+L_{cc})≦0.9,

is satisfied.

[C06] The light emitting device according to [C01] or [C02], in which

a concavo-convex portion is formed on a surface of a part of the substrate adjacent to the first light reflection layer, and

a concave portion constitutes the seed crystal layer growth region.

[C07] The light emitting device according to [C06], in which

the cross-sectional shape obtained by cutting a part of the substrate adjacent to the first light reflection layer on the virtual vertical surface including a normal line that passes the central point of the first light reflection layer is a shape in which the convex portion, the concave portion, and the convex portion are arranged in the stated order, and

the bottom surface of the concave portion constitutes the seed crystal layer growth region.

[C08] The light emitting device according to [C07], in which

when the length of the concave portion and the total length of the convex portion in the virtual vertical surface are respectively represented by L_{cc} and L_{cv}, the following relationship,

0.2≦L_{cc}/(L_{cv}+L_{cc})≦0.9,

is satisfied.

[C09] The light emitting device according to [C01] or [C02], in which

a part of a substrate adjacent to the first light reflection layer has a structure in which a non-crystal growth portion, a flat portion, and a non-crystal growth portion are arranged in the stated order, and

the flat portion constitutes the seed crystal layer growth region.

[C10] The light emitting device according to [C09], in which

when the length of the flat portion and the total length of the non-crystal growth portion in the virtual vertical surface including a normal line that passes through the central point of the first light reflection layer are respectively represented by L_{flat} and Lₙₒᵥ, the following relationship,

0.2≦L_{flat}/(L_{flat}+Lₙₒ)≦0.9,

is satisfied.

[C11] The light emitting device according to [C01] or [C02], in which

a part of the substrate adjacent to the first light reflection layer has a structure in which the concavo-convex portion, the flat portion, and a concavo-convex portion are arranged in the stated order, and

the flat portion constitutes the seed crystal layer growth region.

[C12] The light emitting device according to [C11], in which

when the length of the flat portion and the total length of the concavo-convex portion in the virtual vertical surface including a normal line that passes the central point of the first light reflection layer are respectively referred to as L_{flat} and L_{cc-cv}, the following relationship,

0.2≦L_{flat}/(L_{flat}+L_{cc-cv})≦0.9,

is satisfied.

[C13] The light emitting device according to any one of [C01] to [C12], in which

the cross-sectional shape of the seed crystal layer is an isosceles triangle, an isosceles trapezoid, or a rectangular shape.

[C14] The light emitting device according to any one of [C01] to [C13], in which

when the length of a region of the substrate located between the first light reflection layer and the selective growth mask layer adjacent thereto when the light emitting device is cut on the virtual vertical surface including a normal line that passes through the central points of the first light reflection layer and the selective growth mask layer adjacent thereto is represented by L₀,

a dislocation density of a region of the first compound semiconductor layer located on the upper side of the region of the substrate in the virtual vertical surface is represented by D₀, and

a dislocation density of a region of the first compound semiconductor layer located on the region of the first light reflection layer from the edge of the first light reflection layer to the distance L₀ in the virtual vertical surface is represented by D₁, the following relationship,

D₁/D₀≦0.2,

is satisfied.

[D01] The light emitting device according to any one of [A01] to [C14], in which

the substrate is formed of a GaN substrate,

an off-angle of a plane orientation of a surface of the GaN substrate is not more than 0.4 degrees, favorably, not more than 0.40,

when the area of the GaN substrate is represented by S₀, the total area of the selective growth mask layer and the first light reflection layer is not more than 0.8S₀, and

a thermal expansion relaxation film as the lowermost layer of the first light reflection layer is formed on the GaN substrate.

[D02] The light emitting device according to [D01], in which

the thermal expansion relaxation film is formed of at least one kind of material selected from the group consisting of silicon nitride, aluminum oxide, niobium oxide, tantalum oxide, titanium oxide, magnesium oxide, zirconium oxide, and aluminum nitride.

[D03] The light emitting device according to [D01] or [D02], in which

when the thickness of the thermal expansion relaxation film is represented by t₁, the light emission wavelength of the light emitting device is represented by λ₀, and the refractive index of the thermal expansion relaxation film is represented by n₁, the following relationship,

t₁=λ₀/(2n₁),

is satisfied.

[D04] The light emitting device according to any one of [A01] to [C14], in which

the substrate is formed of a GaN substrate,

an off-angle of a plane orientation of a surface of the GaN substrate is not more than 0.4 degrees, favorably, not more than 0.40,

when the area of the GaN substrate is represented by S₀, the total area of the selective growth mask layer and the first light reflection layer is not more than 0.8S₀, and

the linear thermal expansion coefficient CTE of the lowermost layer of the first light reflection layer that is in contact with the GaN substrate satisfies the following relationship,

1×10⁻⁶/K≦CTE≦1×10⁻⁵/K, and favorably,

1×10⁻⁶/K<CTE≦1×10⁻⁵/K.

[D05] The light emitting device according to [D04], in which

the lowermost layer of the first light reflection layer is formed of at least one kind of material selected from the group consisting of silicon nitride, aluminum oxide, niobium oxide, tantalum oxide, titanium oxide, magnesium oxide, zirconium oxide, and aluminum nitride.

[D06] The light emitting device according to [D04] or [D05], in which

when the thickness of the lowermost layer of the first light reflection layer is represented by t₁, the light emission wavelength of the lowermost layer of the first light reflection layer is represented by λ₀, and the refractive index of the thermal expansion relaxation film is represented by n₁, the following relationship,

t₁=λ₀/(2n₁).

[D07] The light emitting device according to any one of [D01] to [D06], in which

the surface roughness Ra of the second compound semiconductor layer is not more than 1.0 nm.

[E01] The light emitting device according to any one of [A01] to [D07], in which

a projection portion is formed in the first surface of the first compound semiconductor layer opposed to the active layer, the first light reflection layer is formed on this projection portion, and the first electrode is formed in a concave portion on the periphery of the projection portion formed on the first surface of the first compound semiconductor layer.

[E02] The light emitting device according to [E01], in which

a side surface of the projection portion, a dielectric layer is formed.

[E03] The light emitting device according to [E02], in which

the value of the refractive index of the material constituting the dielectric layer is smaller than that of the value of the average refractive index of the material constituting the first compound semiconductor layer.

[E04] The light emitting device according to any one of [A01] to [D07], in which

the first light reflection layer is formed on the first surface of the first compound semiconductor layer opposed to the active layer,

a groove portion is formed on the first surface of the first compound semiconductor layer so as to surround the first light reflection layer, and

the groove portion is filled with an insulating material.

[F01] The light emitting device according to any one of [A01] to [E04], in which

the active layer has a multiquantum well structure including a tunnel barrier layer, and

the composition fluctuation of a well layer adjacent to the second compound semiconductor layer is larger than that of a different well layer.

[F02] The light emitting device according to [F01], in which

the band gap energy of a well layer adjacent to the second compound semiconductor layer is smaller than that of a different well layer.

[F03] The light emitting device according to [F01], in which

the thickness of a well layer adjacent to the second compound semiconductor layer is larger than that of a different well layer.

[F04] The light emitting device according to [F03], in which

the band gap energy of a well layer adjacent to the second compound semiconductor layer is smaller than that of a different well layer.

[F05] The light emitting device according to any one of [F01] to [F04], in which

the tunnel barrier layer is formed between the well layer and the barrier layer.

[G01] The light emitting device according to any one of [A01] to [E04], in which

the active layer has a multiquantum well structure including a tunnel barrier layer, and

the band gap energy of a well layer adjacent to the second compound semiconductor layer is smaller than that of a different well layer.

[G02] The light emitting device according to [G01], in which

the thickness of a well layer adjacent to the second compound semiconductor layer is larger than that of a different well layer.

[G03] The light emitting device according to [G01] or [G02], in which

the tunnel barrier layer is formed between the well layer and the barrier layer.

[H01] The light emitting device according to any one of [A01] to [E04], in which

the active layer has a multiquantum well structure including a tunnel barrier layer, and

the thickness of a well layer adjacent to the second compound semiconductor layer is larger than that of a different well layer.

[H02] The light emitting device according to [H01], in which

the tunnel barrier layer is formed between the well layer and the barrier layer.

[J01] The light emitting device according to any one of [F01] to [H02], in which

the thickness of the tunnel barrier layer is not more than 4 nm.

[K01] (Method of manufacturing light emitting device)

A method of manufacturing a light emitting device, including:

(A) forming a selective growth mask layer and a first light reflection layer thinner than the selective growth mask layer on a substrate; then,

(B) forming a first compound semiconductor layer on an entire surface, then polishing the first compound semiconductor layer by using the selective growth mask layer as a polishing stopper layer, and thereby removing the first compound semiconductor layer on the selective growth mask layer and leaving the first compound semiconductor layer on the first light reflection layer; after that,

(C) forming an active layer and a second compound semiconductor layer on an entire surface; and then,

(D) forming a second electrode and a second light reflection layer opposed to the first light reflection layer on the second compound semiconductor layer.

[K02] The method of manufacturing the light emitting device according [K01], in which

the step (B) includes forming a lower layer of the first compound semiconductor layer on the entire surface, then polishing the lower layer of the first compound semiconductor layer by using the selective growth mask layer as a polishing stopper layer, and thereby removing the lower layer of the first compound semiconductor layer on the selective growth mask layer and leaving the lower layer of the first compound semiconductor layer on the first light reflection layer, and

the step (C) includes forming an upper layer of the first compound semiconductor layer, the active layer, and the second compound semiconductor layer on the entire surface.

[K03] The method of manufacturing the light emitting device according to [K01], further including

removing the selective growth mask layer between the step (B) and the step (C).

### REFERENCE SIGNS LIST

11 substrate (GaN substrate)
11A concave portion of substrate
11B convex portion of substrate
20 laminated structure
21 first compound semiconductor layer
21a first surface of first compound semiconductor layer
21b second surface of first compound semiconductor layer
21c projection portion provided to first compound semiconductor layer
21d side surface (side wall) of convex portion
21e concave portion on periphery of convex portion
22 second compound semiconductor layer
22a first surface of second compound semiconductor layer
22b second surface of second compound semiconductor layer
23 active layer (light emitting layer)
24 current constriction layer
24A opening provided to current constriction layer
25 junction layer
26 supporting substrate
27 dielectric layer
28 insulating material layer
29 impurity-containing compound semiconductor layer
31 first electrode
32 second electrode
33 pad electrode
41 first light reflection layer
42 second light reflection layer
43A base layer
43A′ part of base layer
43B, 43C, 43D dielectric multilayer film
44 selective growth mask layer
45 polishing stopper layer
46 thermal expansion relaxation film
47 uppermost layer of first light reflection layer (selective growth mask layer)
51 surface region of substrate (surface of part of substrate adjacent to first light reflection layer)
52 seed crystal layer growth region
53, 54 concavo-convex portion
53A, 54A convex portion
53B, 54B concave portion
55A flat portion
55B non-crystal growth portion
56A flat portion
56B concavo-convex portion
61 seed crystal layer
62 seed crystal
63 dislocation
711, 712 well layer
72 barrier layer
731, 732 tunnel barrier layer

1. A light emitting device, comprising:
a selective growth mask layer;
a first light reflection layer thinner than the selective growth mask layer;
a laminated structure including a first compound semiconductor layer, an active layer, and a second compound semiconductor layer, the first compound semiconductor layer being formed on the first light reflection layer; and
a second electrode formed on the second compound semiconductor layer, and a second light reflection layer, wherein
the second light reflection layer is opposed to the first light reflection layer.

2. The light emitting device according to claim 1, wherein
a difference between a thickness of the selective growth mask layer and a thickness of the first light reflection layer is not less than 5×10⁻⁸ m.

3. The light emitting device according to claim 1, wherein
the first light reflection layer is formed of a dielectric multilayer film, and
the selective growth mask layer includes, from a side of the active layer, a dielectric multilayer film having the same configuration as that of the dielectric multilayer film constituting the first light reflection layer, and a base layer.

4. The light emitting device according to claim 1, wherein
the first light reflection layer is formed of a dielectric multilayer film, and
the selective growth mask layer includes, from a side of the active layer, a polishing stopper layer and a dielectric multilayer film having the same configuration as that of the dielectric multilayer film constituting the first light reflection layer.

5. The light emitting device according to claim 1, wherein
the selective growth mask layer and the first light reflection layer are formed on a substrate,
the substrate has a concave portion and a convex portion,
the selective growth mask layer is formed in the convex portion of the substrate, and
the first light reflection layer is formed in the concave portion of the substrate.

6. The light emitting device according to claim 5, wherein
the selective growth mask layer is formed of a dielectric multilayer film having the same configuration as that of the dielectric multilayer film constituting the first light reflection layer.

7. The light emitting device according to claim 1, wherein
the selective growth mask layer is formed of a dielectric multilayer film with a thickness different from that of the dielectric multilayer film constituting the first light reflection layer.

8. The light emitting device according to claim 1, wherein
the laminated structure includes an impurity-containing compound semiconductor layer.

9. The light emitting device according to claim 8, wherein
an impurity concentration of the impurity-containing compound semiconductor layer is not less than 10 times an impurity concentration of a compound semiconductor layer adjacent to the impurity-containing compound semiconductor layer.

10. The light emitting device according to claim 8, wherein
an impurity concentration of the impurity-containing compound semiconductor layer is not less than 1×10¹⁷/cm³.

11. The light emitting device according to claim 8, wherein
an impurity contained in the impurity-containing compound semiconductor layer includes at least one kind of element selected from the group consisting of boron, potassium, calcium, sodium, silicon, aluminum, oxygen, carbon, sulfur, chlorine, fluorine, and chromium.

12. A method of manufacturing a light emitting device, comprising:
(A) forming a selective growth mask layer and a first light reflection layer thinner than the selective growth mask layer on a substrate; then,
(B) forming a first compound semiconductor layer on an entire surface, then polishing the first compound semiconductor layer by using the selective growth mask layer as a polishing stopper layer, and thereby removing the first compound semiconductor layer on the selective growth mask layer and leaving the first compound semiconductor layer on the first light reflection layer; after that,
(C) forming an active layer and a second compound semiconductor layer on an entire surface; and then,
(D) forming a second electrode and a second light reflection layer opposed to the first light reflection layer on the second compound semiconductor layer.

13. The method of manufacturing the light emitting device according to claim 12, wherein
the step (B) includes forming a lower layer of the first compound semiconductor layer on the entire surface, then polishing the lower layer of the first compound semiconductor layer by using the selective growth mask layer as a polishing stopper layer, and thereby removing the lower layer of the first compound semiconductor layer on the selective growth mask layer and leaving the lower layer of the first compound semiconductor layer on the first light reflection layer, and
the step (C) includes forming an upper layer of the first compound semiconductor layer, the active layer, and the second compound semiconductor layer on the entire surface.

14. The method of manufacturing the light emitting device according to claim 12, further comprising
removing the selective growth mask layer between the step (B) and the step (C).

15. A light emitting device, comprising:
a first light reflection layer;
a laminated structure including a first compound semiconductor layer, an active layer, and a second compound semiconductor layer, the first compound semiconductor layer being formed on the first light reflection layer;
a second electrode formed on the second compound semiconductor layer, and a second light reflection layer; and
a first electrode, wherein
the second light reflection layer is opposed to the first light reflection layer, and
an impurity-containing compound semiconductor layer is formed in the laminated structure.

16. The light emitting device according to claim 15, wherein
an impurity concentration of the impurity-containing compound semiconductor layer is not less than 10 times an impurity concentration of a compound semiconductor layer adjacent to the impurity-containing compound semiconductor layer.

17. The light emitting device according to claim 15, wherein
an impurity concentration of the impurity-containing compound semiconductor layer is not less than 1×10¹⁷/cm³.

18. The light emitting device according to claim 15, wherein
an impurity contained in the impurity-containing compound semiconductor layer includes at least one kind of element selected from the group consisting of boron, potassium, calcium, sodium, silicon, aluminum, oxygen, carbon, sulfur, chlorine, fluorine, and chromium.
